(19) United States
(12) Patent Application Publication
(10) Pub. No.: US 2026/0107634 A1
(43) Pub. Date: Apr. 16, 2026

(54) DISPLAY DEVICE

(71) Applicant: Samsung Display Co., LTD., Yongin-si, Gyeonggi-do (KR)

(72) Inventor: Gi Chang LEE, Yongin-si (KR)

(21) Appl. No.: 18/917,393

(22) Filed: Oct. 16, 2024

(51) Int. Cl. H10K 59/121; H10K 59/131

(52) U.S. Cl. CPC H10K 59/1213; H10K 59/131

(57) ABSTRACT

The present disclosure relates to a display device, and more particularly, to a display device capable of expanding the area of a display area. The display device includes: a substrate; a pixel circuit on the substrate; a light emitting element connected to the pixel circuit; and a driving circuit connected to the pixel circuit, wherein the light emitting element overlaps the driving circuit.

### CROSS-REFERENCE TO RELATED APPLICATION

The present application claims priority to and the benefit of Korean Patent Application No. 10-2024-0030530, filed on Mar. 4, 2024, in the Korean Intellectual Property Office, the entire disclosure of which is incorporated by reference herein.

### BACKGROUND

### 1. Field

The present disclosure relates to a display device, and more particularly, to a display device capable of expanding the area of a display area.

### 2. Description of the Related Art

A head mounted display (HMD) is an image display device that is worn on a user's head in the form of glasses or helmets to form a focus at a close distance in front of the user's eyes. The head mounted display may implement virtual reality (VR) or augmented reality (AR).

The head mounted display magnifies an image displayed on a small display device by using a plurality of lenses, and displays the magnified image. Therefore, the display device applied to the head mounted display needs to provide high-resolution images, for example, images with a resolution of 3000 PPI (Pixels Per Inch) or higher. To this end, an organic light emitting diode on silicon (OLEDoS), which is a high-resolution small organic light emitting display device, is used as the display device applied to the head mounted display. The OLEDoS is an image display device in which an organic light emitting diode (OLED) is disposed on a semiconductor wafer substrate on which a complementary metal oxide semiconductor (CMOS) is disposed.

### SUMMARY

Aspects and features of embodiments of the present disclosure provide a display device capable of expanding the area of a display area.

According to one or more embodiments of the present disclosure, a display device including: a substrate; a pixel circuit on the substrate; a light emitting element connected to the pixel circuit; and a driving circuit connected to the pixel circuit, wherein the light emitting element overlaps the driving circuit.

In one or more embodiments, the light emitting element includes: a first electrode on the substrate; a light emitting layer on the first electrode; and a second electrode on the light emitting layer.

In one or more embodiments, the first electrode of the light emitting element overlaps the driving circuit.

In one or more embodiments, further includes a pixel defining layer on the first electrode of the light emitting element and defining an emission area of the light emitting element.

In one or more embodiments, the emission area overlaps the driving circuit.

In one or more embodiments, the light emitting element overlaps a non-pixel transistor of the driving circuit.

In one or more embodiments, the pixel circuit and the driving circuit are alternately arranged.

In one or more embodiments, the pixel circuit is surrounded by the driving circuit.

In one or more embodiments, the driving circuit includes at least one of: a scan driver connected to the pixel circuit through a scan line; an emission driver connected to the pixel circuit through an emission control line; a data driver connected to the pixel circuit through a data line; or a timing control circuit connected to the scan driver, the emission driver, and the data driver.

In one or more embodiments, further including a reflective electrode layer connected to the light emitting element.

In one or more embodiments, the reflective electrode layer overlaps the driving circuit.

According to one or more embodiments of the present disclosure, a display device includes: a substrate; a plurality of pixel circuits on the substrate; a plurality of light emitting elements respectively connected to the pixel circuits; and a driving circuit connected to at least one pixel circuit, wherein the plurality of light emitting elements includes: a first light emitting element overlapping the driving circuit: and a second light emitting element that does not overlap the driving circuit.

In one or more embodiments, the first light emitting element includes: a first electrode on the substrate; a light emitting layer on the first electrode; and a second electrode on the light emitting layer.

In one or more embodiments, the first electrode overlaps the driving circuit.

In one or more embodiments, further includes a pixel defining layer on the first electrode of the light emitting element and defining an emission area of the first light emitting element.

In one or more embodiments, the emission area overlaps the driving circuit.

In one or more embodiments, the first light emitting element overlaps a non-pixel transistor of the driving circuit.

In one or more embodiments, the driving circuit and a pixel circuit connected to the first light emitting element are alternately arranged.

In one or more embodiments, a pixel circuit connected to the first light emitting element is surrounded by the driving circuit.

In one or more embodiments, the driving circuit includes at least one of: a scan driver connected to the pixel circuit through a scan line; an emission driver connected to the pixel circuit through an emission control line; a data driver connected to the pixel circuit through a data line; or a timing control circuit connected to the scan driver, the emission driver, and the data driver.

According to the display device according to one or more embodiments, the display area may be expanded. Accordingly, the net die of the wafer on which a display panel is manufactured increases, so that the manufacturing cost of the display device may be reduced.

However, effects, aspects, and features of embodiments of the present disclosure are not limited to those exemplified above and various other effects, aspects, and features are incorporated herein.

### BRIEF DESCRIPTION OF THE DRAWINGS

The above and other aspects and features of embodiments of the present disclosure will become more apparent by describing in detail embodiments thereof with reference to the attached drawings, in which:

FIG. 1 is an exploded perspective view showing a display device according to one or more embodiments;

FIG. 2 is a block diagram illustrating a display device according to one or more embodiments;

FIG. 3 is an equivalent circuit diagram of a sub-pixel according to one or more embodiments;

FIG. 4 is a layout diagram illustrating an example of a display panel according to one or more embodiments;

FIGS. 5 and 6 are layout diagrams illustrating embodiments of the display area of FIG. 4;

FIG. 7 is a cross-sectional view illustrating an example of a display panel taken along the line I1-I1′ of FIG. 5;

FIG. 8 is a layout diagram illustrating a part of the display panel according to one or more embodiments;

FIG. 9 is a cross-sectional view taken along the line III-III′ of FIG. 8;

FIG. 10 is a layout diagram of the display panel according to one or more embodiments;

FIG. 11 is a layout diagram of the display panel according to one or more embodiments;

FIG. 12 is a layout diagram of the display panel according to one or more embodiments;

FIG. 13 is a diagram illustrating a part of the display area of the display panel according to one or more embodiments;

FIG. 14 is a diagram illustrating a part of the display area of the display panel according to one or more embodiments;

FIG. 15 is a diagram illustrating a part of the display area of the display panel according to one or more embodiments;

FIG. 16 is a perspective view illustrating a head mounted display according to one or more embodiments;

FIG. 17 is an exploded perspective view illustrating an example of the head mounted display of FIG. 16; and

FIG. 18 is a perspective view illustrating a head mounted display according to one or more embodiments.

### DETAILED DESCRIPTION

Aspects and features of embodiments of the present disclosure and methods to achieve them will become apparent from the descriptions of embodiments hereinbelow with reference to the accompanying drawings. However, the present disclosure is not limited to embodiments disclosed herein but may be implemented in various different ways. The embodiments are provided for making the present disclosure thorough and complete, and for fully conveying the scope of the present disclosure to those skilled in the art. It is to be noted that the scope of the present disclosure is defined by the claims and their equivalents.

As used herein, a phrase “an element A on an element B” refers to that the element A may be disposed directly on the element B and/or the element A may be disposed indirectly on the element B via another element C. As used herein, at least one of A, B and C” or “at least one of A, B, or C” to be A, B, C, AB, AC, or ABC. Also, as used herein, at least one of: A; B; or C” may refer to A, B, C, AB, AC, or ABC. Like reference numerals denote like elements throughout the present disclosure. The figures, dimensions, ratios, angles, numbers of elements given in the drawings are merely illustrative and are not limiting.

Although terms such as first, second, etc. are used to distinguish arbitrarily between the elements such terms describe, and thus these terms are not necessarily intended to indicate temporal or other prioritization of such elements. These terms are used to merely distinguish one element from another. Accordingly, as used herein, a first element may be a second element within the technical scope of the present disclosure.

Features of various embodiments of the present disclosure may be combined partially or totally. As will be clearly appreciated by those skilled in the art, technically various interactions and operations are possible. Various embodiments can be practiced individually or in combination.

Hereinafter, embodiments of the present disclosure will be described with reference to the accompanying drawings.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

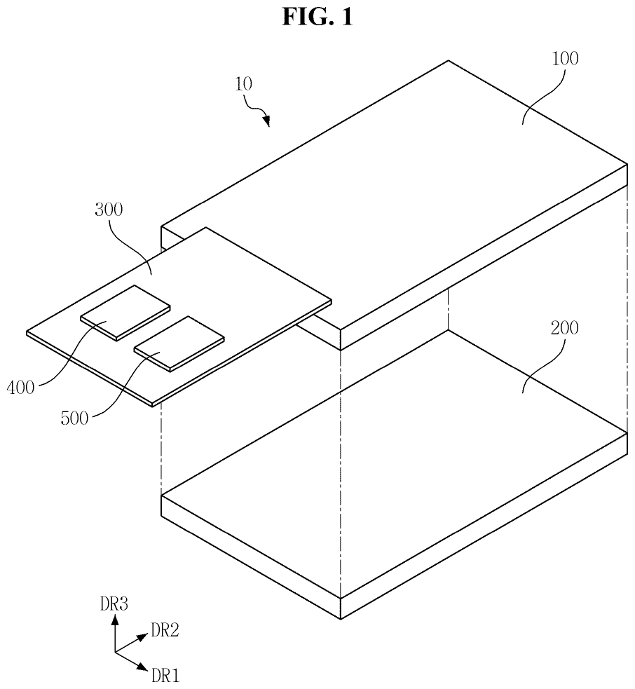

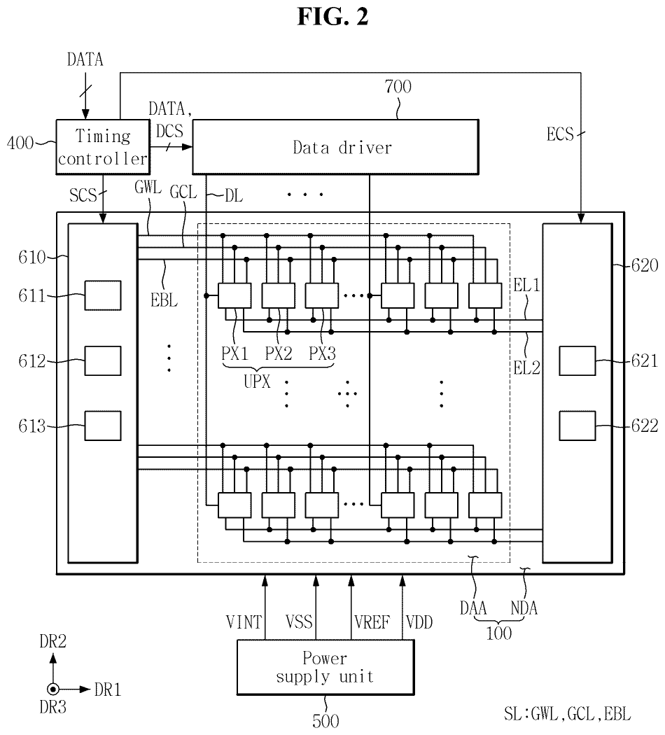

FIG. 1 is an exploded perspective view showing a display device according to one or more embodiments. FIG. 2 is a block diagram illustrating a display device according to one or more embodiments.

Referring to FIGS. 1 and 2, a display device 10 according to one or more embodiments is a device displaying a moving image and/or a still image. The display device 10 according to one or more embodiments may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC), and/or the like. For example, the display device 10 according to one or more embodiments may be applied as a display unit of a television, a laptop, a monitor, a billboard, and/or an Internet-of-Things (IoT) terminal. Alternatively, the display device 10 according to one or more embodiments may be applied to a smart watch, a watch phone, a head mounted display (HMD) for implementing virtual reality and augmented reality, and/or the like.

The display device 10 according to one or more embodiments includes a display panel 100, a heat dissipation layer 200, a circuit board 300, a timing control circuit 400, and a power supply circuit 500.

The display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a suitable curvature (e.g., a predetermined curvature). The planar shape of the display panel 100 is not limited to a quadrilateral shape, and may be a shape similar to another polygonal shape, a circular shape, and/or an elliptical shape. The planar shape of the display device 10 may conform to the planar shape of the display panel 100, but the present disclosure is not limited thereto.

The display panel 100 includes a display area DAA displaying an image and a non-display area NDA not displaying an image as shown in FIG. 2.

The display area DAA includes a plurality of pixels PX, a plurality of scan lines SL, a plurality of emission control lines EL, and a plurality of data lines DL.

The plurality of pixels PX may be arranged in a matrix form in the first direction DR1 and the second direction DR2. For example, the plurality of pixels PX may be arranged along rows and columns of a matrix along the first direction DR1 and the second direction DR2. The plurality of scan lines SL and the plurality of emission control lines EL may extend in the first direction DR1, while being arranged along the second direction DR2. The plurality of data lines DL may extend in the second direction DR2, while being arranged along the first direction DR1.

The plurality of scan lines SL include a plurality of write scan lines GWL, a plurality of control scan lines GCL, and a plurality of bias scan lines EBL. The plurality of emission control lines EL include a plurality of first emission control lines EL1 and a plurality of second emission control lines EL2.

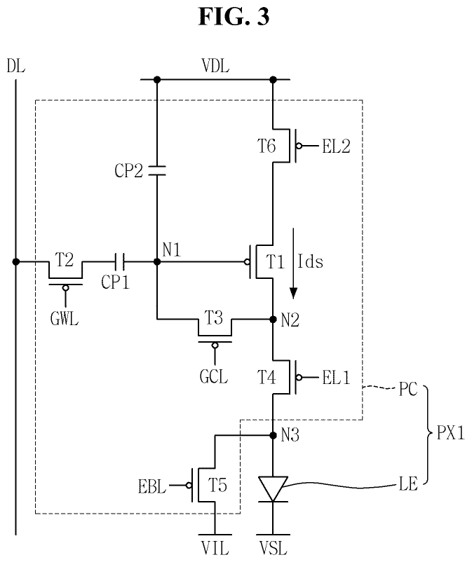

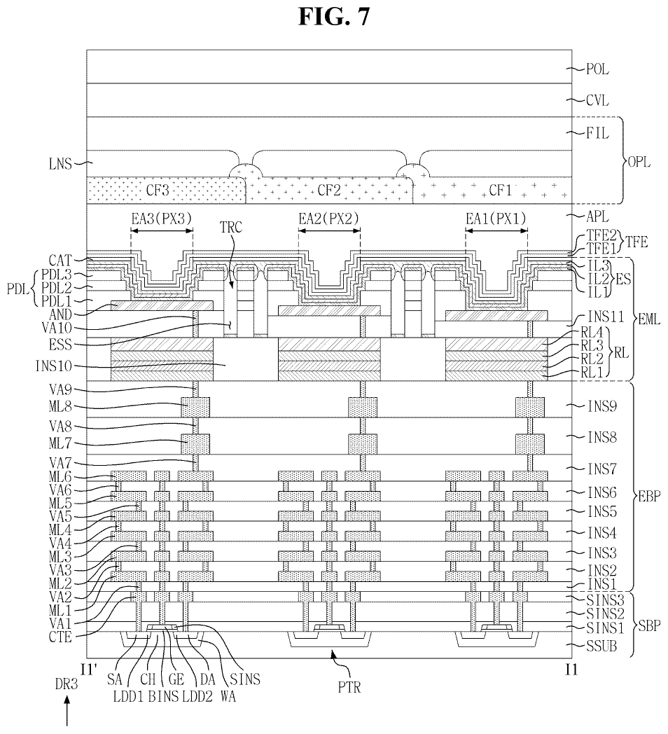

Each of a plurality of unit pixels UPX includes a plurality of pixels PX1, PX2, and PX3. The plurality of pixels PX1, PX2, and PX3 may include a plurality of pixel transistors as shown in FIG. 3, and the plurality of pixel transistors are formed through a semiconductor process and may be disposed on a semiconductor substrate SSUB (see FIG. 7). For example, the plurality of pixel transistors of a data driver 700 may be formed of complementary metal oxide semiconductor (CMOS).

Each of the plurality of pixels PX1, PX2, and PX3 may be connected to any one of the plurality of write scan lines GWL, any one of the plurality of control scan lines GCL, any one of the plurality of bias scan lines EBL, any one of the plurality of first emission control lines EL1, any one of the plurality of second emission control lines EL2, and any one of the plurality of data lines DL. Each of the plurality of pixels PX1, PX2, and PX3 may receive a data voltage of the data line DL in response to a write scan signal of the write scan line GWL, and emit light from the light emitting element according to the data voltage.

The non-display area NDA includes a scan driver 610, an emission driver 620, and the data driver 700.

The scan driver 610 includes a plurality of scan transistors, and the emission driver 620 includes a plurality of light emitting transistors. The plurality of scan transistors and the plurality of light emitting transistors may be formed on the semiconductor substrate SSUB (see FIG. 7) through a semiconductor process. For example, the plurality of scan transistors and the plurality of light emitting transistors may be formed of CMOS. Although it is illustrated in FIG. 2 that the scan driver 610 is disposed on the left side of the display area DAA and the emission driver 620 is disposed on the right side of the display area DAA, the present disclosure is not limited thereto. For example, the scan driver 610 and the emission driver 620 may be disposed on both the left side and the right side of the display area DAA.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to bias scan lines EBL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines EL1. The second emission control driver 622 may generate second emission control signals according to the emission timing control signal ECS and sequentially output them to the second emission control lines EL2.

The data driver 700 may include a plurality of data transistors, and the plurality of data transistors may be formed on the semiconductor substrate SSUB (see FIG. 7) through a semiconductor process. For example, the plurality of data transistors may be formed of CMOS.

The data driver 700 may receive digital video data DATA and a data timing control signal DCS from the timing control circuit 400. The data driver 700 converts the digital video data DATA into analog data voltages according to the data timing control signal DCS and outputs the analog data voltages to data lines DL. In this case, the pixels PX1, PX2, and PX3 are selected by the write scan signal of the scan driver 610, and data voltages may be supplied to the selected pixels PX1, PX2, and PX3.

The heat dissipation layer 200 may overlap the display panel 100 in a third direction DR3, which is the thickness direction of the display panel 100. The heat dissipation layer 200 may be disposed on one surface of the display panel 100, for example, on the rear surface thereof. The heat dissipation layer 200 serves to dissipate heat generated from the display panel 100. The heat dissipation layer 200 may include a metal layer such as graphite, silver (Ag), copper (Cu), and/or aluminum (Al) having high thermal conductivity.

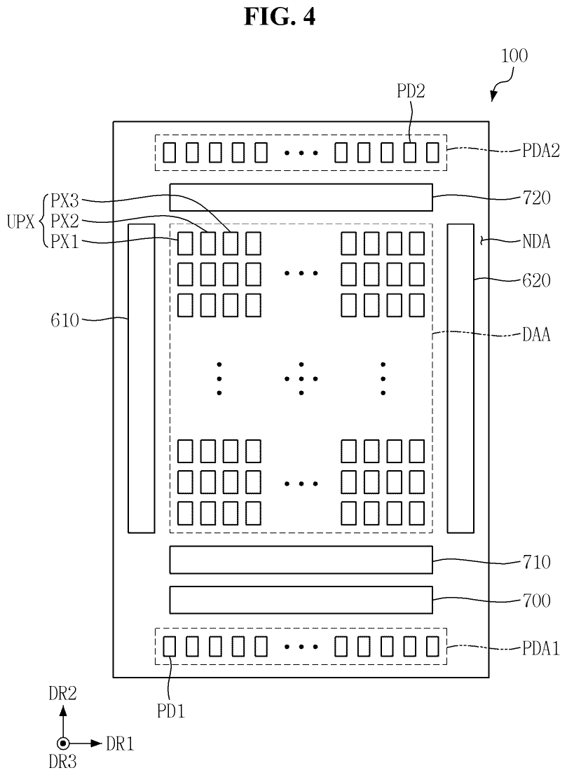

The circuit board 300 may be electrically connected to a plurality of first pads PD1 (see FIG. 4) of a first pad portion PDA1 (see FIG. 4) of the display panel 100 by using a conductive adhesive member such as an anisotropic conductive film. The circuit board 300 may be a flexible printed circuit board (FPCB) with a flexible material, and/or a flexible film. Although the circuit board 300 is illustrated in FIG. 1 as being unfolded, the circuit board 300 may be bent. In this case, one end of the circuit board 300 may be disposed on the rear surface of the display panel 100 and/or the rear surface of the heat dissipation layer 200. One end of the circuit board 300 may be an opposite end of the other end of the circuit board 300 connected to the plurality of first pads PD1 (see FIG. 4) of the first pad portion PDA1 (see FIG. 4) of the display panel 100 by using a conductive adhesive member.

The timing control circuit 400 may receive digital video data DATA and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data DATA and the data timing control signal DCS to the data driver 700.

The power supply circuit 500 may generate a plurality of panel driving voltages according to a power voltage from the outside. For example, the power supply circuit 500 may generate a common voltage VSS, a driving voltage VDD, a reference voltage VREF, and an initialization voltage VINT and supply them to the display panel 100. The common voltage VSS, the driving voltage VDD, the reference voltage VREF, and the initialization voltage VINT will be described later in conjunction with FIG. 3.

Each of the timing control circuit 400 and the power supply circuit 500 may be formed as an integrated circuit (IC) and attached to one surface of the circuit board 300. In this case, the scan timing control signal SCS, the emission timing control signal ECS, the digital video data DATA, and the data timing control signal DCS of the timing control circuit 400 may be supplied to the display panel 100 through the circuit board 300. In addition, the common voltage VSS, the driving voltage VDD, the reference voltage VREF, and the initialization voltage VINT of the power supply circuit 500 may be supplied to the display panel 100 through the circuit board 300.

Alternatively, each of the timing control circuit 400 and the power supply circuit 500 may be disposed in the non-display area NDA of the display panel 100, similarly to the scan driver 610, the emission driver 620, and the data driver 700. In this case, the timing control circuit 400 may include a plurality of timing transistors, and each power supply circuit 500 may include a plurality of power transistors. The plurality of timing transistors and the plurality of power transistors may be formed on a semiconductor substrate SSUB (see FIG. 7) through a semiconductor process. For example, the plurality of timing transistors and the plurality of power transistors may be formed of CMOS. Each of the timing control circuit 400 and the power supply circuit 500 may be disposed between the data driver 700 and the first pad portion PDA1 (see FIG. 4).

The above-described scan transistors, light emitting transistors, data transistors, timing transistors, and power transistors may be defined as non-pixel transistors. In other words, the non-pixel transistors may include the scan transistors, the light emitting transistors, the data transistors, the timing transistors, and the power transistors described above.

FIG. 3 is an equivalent circuit diagram of a sub-pixel according to one or more embodiments.

Referring to FIG. 3, the first pixel PX1 may be connected to the write scan line GWL, the control scan line GCL, the bias scan line EBL, the first emission control line EL1, the second emission control line EL2, and the data line DL. In addition, the first pixel PX1 may be connected to a common voltage line VSL to which the common voltage VSS corresponding to a low potential voltage is applied, a driving voltage line VDL to which the driving voltage VDD corresponding to a high potential voltage is applied, and an initialization voltage line VIL to which the initialization voltage VINT is applied. That is, the common voltage line VSL may be a low potential voltage line, the driving voltage line VDL may be a high potential voltage line, and the initialization voltage line VIL may be an initialization voltage line. In this case, the common voltage VSS may be lower than the initialization voltage VINT. The driving voltage VDD may be higher than the initialization voltage VINT.

The first pixel PX1 may include a pixel circuit PC and a light emitting element LE connected to the pixel circuit PC.

The pixel circuit PC may include a plurality of transistors T1 to T6, a first capacitor CP1, and a second capacitor CP2.

The light emitting element LE emits light in response to a driving current Ids flowing through the channel of the first transistor T1. The emission amount of the light emitting element LE may be proportional to the driving current Ids. The light emitting element LE may be disposed between the fourth transistor T4 and the common voltage line VSL. The first electrode of the light emitting element LE may be connected to the drain electrode of the fourth transistor T4, and the second electrode thereof may be connected to the common voltage line VSL. The first electrode of the light emitting element LE may be an anode electrode, and the second electrode of the light emitting element LE may be a cathode electrode. The light emitting element LE may be an organic light emitting diode (OLED) including a first electrode, a second electrode, and an organic light emitting layer disposed between the first electrode and the second electrode, but the present disclosure is not limited thereto. For example, the light emitting element LE may be an inorganic light emitting element including a first electrode, a second electrode, and an inorganic semiconductor disposed between the first electrode and the second electrode, in which case the light emitting element LE may be a micro light emitting diode.

The first transistor T1 may be a driving transistor that controls a source-drain current Ids (hereinafter referred to as a “driving current”) flowing between the source electrode and the drain electrode thereof according to a voltage applied to the gate electrode thereof. The first transistor T1 includes a gate electrode connected to a first node N1, a source electrode connected to the drain electrode of the sixth transistor T6, and a drain electrode connected to a second node N2.

The second transistor T2 may be disposed between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1. The second transistor T2 includes a gate electrode connected to the write scan line GWL, a source electrode connected to the data line DL, and a drain electrode connected to the one electrode of the first capacitor CP1.

The third transistor T3 may be disposed between the first node N1 and the second node N2. The third transistor T3 is turned on by the write control signal of the write control line GCL to connect the first node N1 to the second node N2. For this reason, because the gate electrode and the source electrode of the first transistor T1 are connected when the third transistor T3 is turned on, the first transistor T1 may operate like a diode (e.g., the first transistor T1 may be diode-connected). The third transistor T3 includes a gate electrode connected to the write control line GCL, a source electrode connected to the second node N2, and a drain electrode connected to the first node N1.

The fourth transistor T4 may be connected between the second node N2 and a third node N3. The fourth transistor T4 is turned on by the first emission control signal of the first emission control line EL1 to connect the second node N2 to the third node N3. Accordingly, the driving current of the first transistor T1 may be supplied to the light emitting element LE via the fourth transistor T4 and the third node N3. The fourth transistor T4 includes a gate electrode connected to the first emission control line EL1, a source electrode connected to the second node N2, and a drain electrode connected to the third node N3.

The fifth transistor T5 may be disposed between the third node N3 and the initialization voltage line VIL. The fifth transistor T5 is turned on by the bias scan signal of the bias scan line EBL to connect the third node N3 to the initialization voltage line VIL. Accordingly, the initialization voltage VINT of the initialization voltage line VIL may be applied to the first electrode of the light emitting element LE. The fifth transistor T5 includes a gate electrode connected to the bias scan line EBL, a source electrode connected to the third node N3, and a drain electrode connected to the initialization voltage line VIL.

The sixth transistor T6 may be disposed between the source electrode of the first transistor T1 and the driving voltage line VDL. The sixth transistor T6 is turned on by the second emission control signal of the second emission control line EL2 to connect the source electrode of the first transistor T1 to the driving voltage line VDL. Accordingly, the driving voltage VDD of the driving voltage line VDL may be applied to the source electrode of the first transistor T1. The sixth transistor T6 includes a gate electrode connected to the second emission control line EL2, a source electrode connected to the driving voltage line VDL, and a drain electrode connected to the source electrode of the first transistor T1.

The first capacitor CP1 is formed between the first node N1 and the drain electrode of the second transistor T2. The first capacitor CP1 includes one electrode connected to the drain electrode of the second transistor T2 and the other electrode connected to the first node N1.

The second capacitor CP2 is formed between the gate electrode of the first transistor T1 or the first node N1 and the driving voltage line VDL. The second capacitor CP2 includes one electrode connected to the gate electrode of the first transistor T1 or the first node N1 and the other electrode connected to the driving voltage line VDL.

The first node N1 is a junction between the gate electrode of the first transistor T1, the drain electrode of the third transistor T3, the other electrode of the first capacitor CP1, and the one electrode of the second capacitor CP2. The second node N2 is a junction between the drain electrode of the first transistor T1, the source electrode of the third transistor T3, and the source electrode of the fourth transistor T4. The third node N3 is a junction between the drain electrode of the fourth transistor T4, the source electrode of the fifth transistor T5, and the first electrode of the light emitting element LE.

Each of the first to sixth transistors T1 to T6 may be a metal-oxide-semiconductor field effect transistor (MOSFET). For example, each of the first to sixth transistors T1 to T6 may be a P-type MOSFET, but the present disclosure is not limited thereto. Each of the first to sixth transistors T1 to T6 may be an N-type MOSFET. Alternatively, some of the first to sixth transistors T1 to T6 may be P-type MOSFETs, and each of the remaining transistors may be an N-type MOSFET.

Although it is illustrated in FIG. 3 that the first pixel PX1 includes six transistors T1 to T6 and the two capacitors C1 and C2, the equivalent circuit diagram of the first pixel PX1 is not limited to the example shown in FIG. 3. For example, the number of the transistors and the number of the capacitors of the first pixel PX1 are not limited to the example shown in FIG. 3.

In addition, the equivalent circuit diagram of the second pixel PX2 and the equivalent circuit diagram of the third pixel PX3 may be substantially the same as the equivalent circuit diagram of the first pixel PX1 described in conjunction with FIG. 3. Thus, in the present disclosure, description of the equivalent circuit diagram of the second pixel PX2 and the equivalent circuit diagram of the third pixel PX3 will be omitted.

FIG. 4 is a layout diagram illustrating an example of a display panel according to one or more embodiments.

Referring to FIG. 4, the display area DAA of the display panel 100 according to one or more embodiments includes the plurality of pixels PX arranged in a matrix form. The non-display area NDA of the display panel 100 according to one or more embodiments include the scan driver 610, the emission driver 620, the data driver 700, a first distribution circuit 710, a second distribution circuit 720, the first pad portion PDA1, and a second pad portion PDA2.

The scan driver 610 may be disposed on the first side of the display area DAA, and the emission driver 620 may be disposed on the second side of the display area DAA. For example, the scan driver 610 may be disposed on one side of the display area DAA in the first direction DR1, and the emission driver 620 may be disposed on the other side of the display area DAA in the first direction DR1. That is, the scan driver 610 may be disposed on the left side of the display area DAA, and the emission driver 620 may be disposed on the right side of the display area DAA. However, the present disclosure is not limited thereto, and the scan driver 610 and the emission driver 620 may be disposed on both the first side and the second side of the display area DAA.

The first pad portion PDA1 may include the plurality of first pads PD1 connected to pads or bumps of the circuit board 300 through a conductive adhesive member. The first pad portion PDA1 may be disposed on the third side of the display area DAA. For example, the first pad portion PDA1 may be disposed on one side of the display area DAA in the second direction DR2.

The first pad portion PDA1 may be disposed outside the data driver 700 in the second direction DR2. That is, the first pad portion PDA1 may be disposed closer to the edge of the display panel 100 than the data driver 700 is.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board (PCB) made of a rigid material or a flexible printed circuit board (FPCB) made of a flexible material.

The first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be disposed on the third side of the display area DAA of the display panel 100. For example, the first distribution circuit 710 may be disposed on one side of the display area DAA in the second direction DR2. That is, the first distribution circuit 710 may be disposed on the lower side of the display area DAA.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the display area DAA of the display panel 100. For example, the second distribution circuit 720 may be disposed on the other side of the display area DAA in the second direction DR2. That is, the second distribution circuit 720 may be disposed on the upper side of the display area DAA.

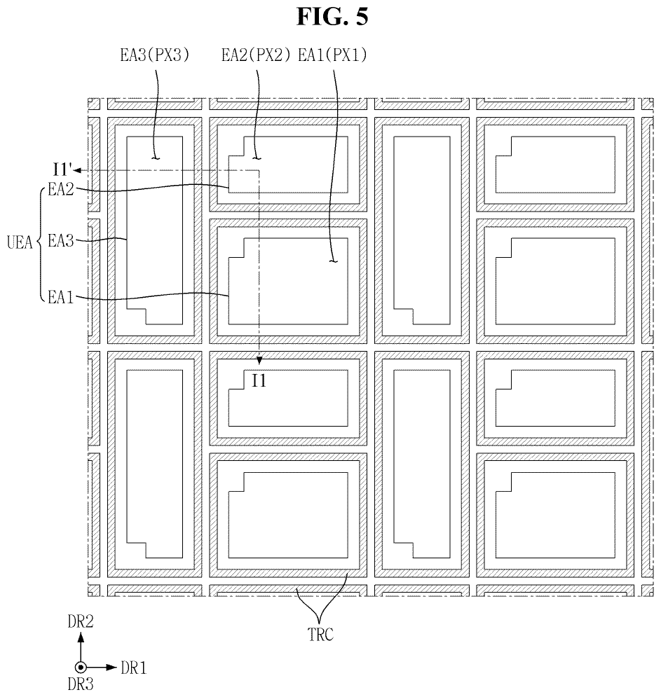

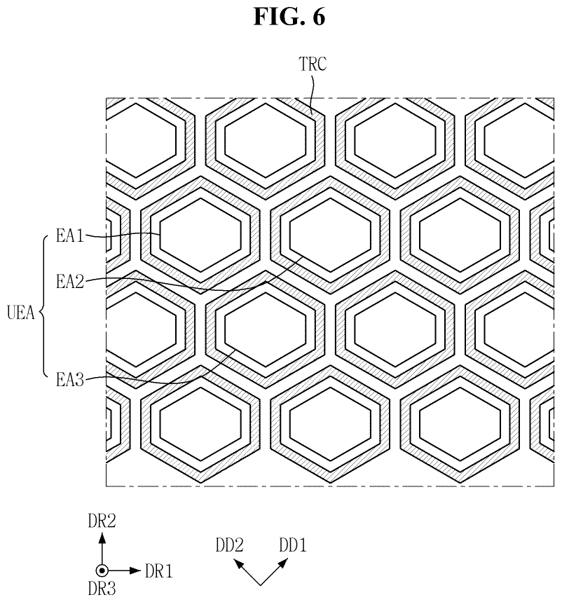

FIGS. 5 and 6 are layout diagrams illustrating embodiments of the display area of FIG. 4.

Referring to FIGS. 5 and 6, each of the plurality of unit pixels UPX includes a first emission area EA1 as an emission area of the first pixel PX1, a second emission area EA2 as an emission area of the second pixel PX2, and a third emission area EA3 as an emission area of the third pixel PX3. In other words, the unit pixel UPX may include a unit emission area UEA, and the unit emission area UEA includes the first emission area EA1, the second emission area EA2, and the third emission area EA3 described above.

Referring to FIGS. 5 and 6, each of the plurality of pixels PX includes the first emission area EA1 as an emission area of the first pixel PX1, the second emission area EA2 as an emission area of the second pixel PX2, and the third emission area EA3 as an emission area of the third pixel PX3.

Each of the first emission area EA1, the second emission area EA2, and the third emission area EA3 may have a polygonal, circular, elliptical, and/or atypical shape in a plan view.

The maximum length of the third emission area EA3 in the first direction DR1 may be smaller than the maximum length of the second emission area EA2 in the first direction DR1 and the maximum length of the first emission area EA1 in the first direction DR1. The maximum length of the second emission area EA2 in the first direction DR1 and the maximum length of the first emission area EA1 in the first direction DR1 may be substantially the same.

The maximum length of the third emission area EA3 in the second direction DR2 may be greater than the maximum length of the second emission area EA2 in the second direction DR2 and the maximum length of the first emission area EA1 in the second direction DR2. The maximum length of the second emission area EA2 in the second direction DR2 may be less than the maximum length of the first emission area EA1 in the second direction DR2. The maximum length of the third emission area EA3 in the second direction DR2 may be greater than the maximum length of the second emission area EA2 in the second direction DR2.

The first emission area EA1, the second emission area EA2, and the third emission area EA3 may have, in a plan view, a hexagonal shape formed of six straight lines as shown in FIGS. 5 and 6, but the present disclosure is not limited thereto. The first emission area EA1, the second emission area EA2, and the third emission area EA3 may have a polygonal shape other than a hexagon, a circular shape, an elliptical shape, and/or an atypical shape in a plan view.

As shown in FIG. 5, in each of the plurality of pixels PX, the third emission area EA3 and the second emission area EA2 may be adjacent to each other in the first direction DR1. Further, the first emission area EA1 and the third emission area EA3 may be adjacent to each other in the first direction DR1. In addition, the second emission area EA2 and the first emission area EA1 may be adjacent to each other in the second direction DR2. The area of the first emission area EA1, the area of the second emission area EA2, and the area of the third emission area EA3 may be different.

Alternatively, as shown in FIG. 6, the first emission area EA1 and the second emission area EA2 may be adjacent to each other in the first direction DR1, but the second emission area EA2 and the third emission area EA3 may be adjacent to each other in a first diagonal direction DD1, and the first emission area EA1 and the third emission area EA3 may be adjacent to each other in a second diagonal direction DD2. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction perpendicular to the first diagonal direction DD1.

The first emission area EA1 may emit light of a first color, the second emission area EA2 may emit light of a second color, and the third emission area EA3 may emit light of a third color. Here, the light of the first color may be light of a blue wavelength band, the light of the second color may be light of a green wavelength band, and the light of the third color may be light of a red wavelength band. For example, the blue wavelength band may be a wavelength band of light whose main peak wavelength is in the range of about 370 nm to about 460 nm, the green wavelength band may be a wavelength band of light whose main peak wavelength is in the range of about 480 nm to about 560 nm, and the red wavelength band may be a wavelength band of light whose main peak wavelength is in the range of about 600 nm to about 750 nm.

It is shown as an example in FIGS. 5 and 6 that each of the plurality of pixels PX includes three emission areas EA1, EA2, and EA3, but the present disclosure is not limited thereto. That is, each of the plurality of pixels PX may include four emission areas.

In addition, the layout of the emission areas of the plurality of pixels PX is not limited to that illustrated in FIGS. 5 and 6. For example, the emission areas of the plurality of pixels PX may be disposed in a stripe structure in which the emission areas are arranged along the first direction DR1, a PENTILE® structure in which the emission areas are arranged in a diamond shape, or a hexagonal structure in which the emission areas having, in a plan view, a hexagonal shape are arranged side by side as shown in FIG. 6. The PENTILE® pixel arrangement structure may be referred to as an RGBG matrix structure (e.g., a PENTILE® matrix structure or an RGBG structure (e.g., a PENTILE® structure)). PENTILE® is a registered trademark of Samsung Display Co., Ltd., Republic of Korea.

FIG. 7 is a cross-sectional view illustrating an example of a display panel taken along the line I-1-I1′ of FIG. 5.

Referring to FIG. 7, the display panel 100 includes a semiconductor backplane SBP, a light emitting element backplane EBP, a display element layer EML, an encapsulation layer TFE, an organic layer APL, an optical layer OPL, a cover layer CVL, and a polarizing plate POL.

The semiconductor backplane SBP may include the semiconductor substrate SSUB including a plurality of pixel transistors PTR, a plurality of semiconductor insulating layers covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 4.

The semiconductor substrate SSUB may be a silicon substrate, a germanium substrate, and/or a silicon-germanium substrate. The semiconductor substrate SSUB may be a substrate doped with a first type impurity. A plurality of well regions WA may be disposed on the top surface of the semiconductor substrate SSUB. The plurality of well regions WA may be regions doped with a second type impurity. The second type impurity may be different from the aforementioned first type impurity. For example, when the first type impurity is a p-type impurity, the second type impurity may be an n-type impurity. Alternatively, when the first type impurity is an n-type impurity, the second type impurity may be a p-type impurity.

Each of the plurality of well regions WA includes a source region SA corresponding to the source electrode of the pixel transistor PTR, a drain region DA corresponding to the drain electrode thereof, and a channel region CH disposed between the source region SA and the drain region DA.

A lower insulating layer BINS may be disposed between a gate electrode GE and the well region WA. A side insulating layer SINS may be disposed on the side surface of the gate electrode GE. The side insulating layer SINS may be disposed on the lower insulating layer BINS.

Each of the source region SA and the drain region DA may be a region doped with the first type impurity. The gate electrode GE of the pixel transistor PTR may overlap the well region WA in the third direction DR3. The channel region CH may overlap the gate electrode GE in the third direction DR3. The source region SA may be disposed on one side of the gate electrode GE, and the drain region DA may be disposed on the other side of the gate electrode GE.

Each of the plurality of well regions WA further includes a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating layer BINS. The second low-concentration impurity region LDD2 may be a region having a lower impurity concentration than the drain region DA due to the lower insulating layer BINS. The distance between the source region SA and the drain region DA may increase due to the presence of the first low-concentration impurity region LDD1 and the second low-concentration impurity region LDD2. Therefore, the length of the channel region CH of each of the pixel transistors PTR may increase, so that punch-through and hot carrier phenomena that might be caused by a short channel may be reduced or prevented.

A first semiconductor insulating layer SINS1 may be disposed on the semiconductor substrate SSUB covering the gate electrode GE. The first semiconductor insulating layer SINS1 may be formed of silicon carbonitride (SiCN) and/or a silicon oxide (SiOx)-based inorganic layer, but the present disclosure is not limited thereto.

A second semiconductor insulating layer SINS2 may be disposed on the first semiconductor insulating layer SINS1. The second semiconductor insulating layer SINS2 may be formed of a silicon oxide (SiOx)-based inorganic layer, but the present disclosure is not limited thereto.

The plurality of contact terminals CTE may be disposed on the second semiconductor insulating layer SINS2. Each of the plurality of contact terminals CTE may be connected to one of the gate electrode GE, the source region SA, or the drain region DA of each of the pixel transistors PTR through holes penetrating the first semiconductor insulating layer SINS1 and the second semiconductor insulating layer SINS2. The plurality of contact terminals CTE may be formed of copper (Cu), aluminum (Al), tungsten (W), molybdenum (Mo), chromium (Cr), gold (Au), titanium (Ti), nickel (Ni), and/or neodymium (Nd), and/or an alloy including any one of them.

A third semiconductor insulating layer SINS3 may be disposed on a side surface of each of the plurality of contact terminals CTE on the second semiconductor insulating layer SINS2. The top surface of each of the plurality of contact terminals CTE may be exposed without being covered by the third semiconductor insulating layer SINS3. The third semiconductor insulating layer SINS3 may be formed of a silicon oxide (SiOx)-based inorganic layer, but the present disclosure is not limited thereto.

The semiconductor substrate SSUB may be replaced with a glass substrate and/or a polymer resin substrate such as polyimide. In this case, thin film transistors may be disposed on the glass substrate and/or the polymer resin substrate. The glass substrate may be a rigid substrate that does not bend, and the polymer resin substrate may be a flexible substrate that can be bent and/or curved.

The light emitting element backplane EBP includes a plurality of conductive layers ML1 to ML8, a plurality of vias VA1 to VA9. In addition, the light emitting element backplane EBP includes a plurality of insulating layers INS1 to INS11 disposed between first to eighth conductive layers ML1 to ML8.

The first to eighth conductive layers ML1 to ML8 serve to connect the plurality of contact terminals CTE exposed from the semiconductor backplane SBP to thereby implement the circuit of the first pixel PX1 shown in FIG. 3. For example, the first to sixth transistors T1 to T6 are merely formed on the semiconductor backplane SBP, and the connection of the first to sixth transistors T1 to T6 and the first and second capacitors C1 and C2 is accomplished through the first to eighth conductive layers ML1 to ML8. In addition, the connection between the drain region corresponding to the drain electrode of the fourth transistor T4, the source region corresponding to the source electrode of the fifth transistor T5, and the first electrode of the light emitting element LE is also accomplished through the first to eighth conductive layers ML1 to ML8.

A first insulating layer INS1 may be disposed on the semiconductor backplane SBP. Each of first vias VA1 may penetrate the first insulating layer INS1 to be connected to the contact terminal CTE exposed from the semiconductor backplane SBP. Each of the first conductive layers ML1 may be disposed on the first insulating layer INS1 and may be connected to the first via VA1.

A second insulating layer INS2 may be disposed on the first insulating layer INS1 and the first conductive layers ML1. Each of second vias VA2 may penetrate the second insulating layer INS2 and may be connected to the exposed first conductive layer ML1. Each of the second conductive layers ML2 may be disposed on the second insulating layer INS2 and may be connected to the second via VA2.

A third insulating layer INS3 may be disposed on the second insulating layer INS2 and the second conductive layers ML2. Each of third vias VA3 may penetrate the third insulating layer INS3 and may be connected to the exposed second conductive layer ML2. Each of the third conductive layers ML3 may be disposed on the third insulating layer INS3 and may be connected to the third via VA3.

A fourth insulating layer INS4 may be disposed on the third insulating layer INS3 and the third conductive layers ML3. Each of fourth vias VA4 may penetrate the fourth insulating layer INS4 and may be connected to the exposed third conductive layer ML3. Each of the fourth conductive layers ML4 may be disposed on the fourth insulating layer INS4 and may be connected to the fourth via VA4.

A fifth insulating layer INS5 may be disposed on the fourth insulating layer INS4 and the fourth conductive layers ML4. Each of fifth vias VA5 may penetrate the fifth insulating layer INS5 and may be connected to the exposed fourth conductive layer ML4. Each of the fifth conductive layers ML5 may be disposed on the fifth insulating layer INS5 and may be connected to the fifth via VA5.

A sixth insulating layer INS6 may be disposed on the fifth insulating layer INS5 and the fifth conductive layers ML5. Each of sixth vias VA6 may penetrate the sixth insulating layer INS6 and may be connected to the exposed fifth conductive layer ML5. Each of the sixth conductive layers ML6 may be disposed on the sixth insulating layer INS6 and may be connected to the sixth via VA6.

A seventh insulating layer INS7 may be disposed on the sixth insulating layer INS6 and the sixth conductive layers ML6. Each of seventh vias VA7 may penetrate the seventh insulating layer INS7 and may be connected to the exposed sixth conductive layer ML6. Each of the seventh conductive layers ML7 may be disposed on the seventh insulating layer INS7 and may be connected to the seventh via VA7.

An eighth insulating layer INS8 may be disposed on the seventh insulating layer INS7 and the seventh conductive layers ML7. Each of eighth vias VA8 may penetrate the eighth insulating layer INS8 and may be connected to the exposed seventh conductive layer ML7. Each of the eighth conductive layers ML8 may be disposed on the eighth insulating layer INS8 and may be connected to the eighth via VA8.

The first to eighth conductive layers ML1 to ML8 and the first to eighth vias VA1 to VA8 may be formed of substantially the same material. The first to eighth conductive layers ML1 to ML8 and the first to eighth vias VA1 to VA8 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. The first to eighth vias VA1 to VA8 may be made of substantially the same material. The first to eighth insulating layers INS1 to INS8 may be formed of a silicon oxide (SiOx)-based inorganic layer, but the present disclosure is not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be greater than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be approximately 1360 Å; the thickness of each of the second conductive layer ML2, the third conductive layer ML3, the fourth conductive layer ML4, the fifth conductive layer ML5, and the sixth conductive layer ML6 may be approximately 1440 Å; and the thickness of each of the first via VA1, the second via VA2, the third via VA3, the fourth via VA4, the fifth via VA5, and the sixth via VA6 may be approximately 1150 Å.

The thickness of each of the seventh conductive layer ML7 and the eighth conductive layer ML8 may be greater than the thickness of the first conductive layer ML1, the thickness of the second conductive layer ML2, the thickness of the third conductive layer ML3, the thickness of the fourth conductive layer ML4, the thickness of the fifth conductive layer ML5, and the thickness of the sixth conductive layer ML6. The thickness of the seventh conductive layer ML7 and the thickness of the eighth conductive layer ML8 may be greater than the thickness of the seventh via VA7 and the thickness of the eighth via VA8, respectively. The thickness of each of the seventh via VA7 and the eighth via VA8 may be greater than the thickness of the first via VA1, the thickness of the second via VA2, the thickness of the third via VA3, the thickness of the fourth via VA4, the thickness of the fifth via VA5, and the thickness of the sixth via VA6. The thickness of the seventh conductive layer ML7 and the thickness of the eighth conductive layer ML8 may be substantially the same. For example, the thickness of each of the seventh conductive layer ML7 and the eighth conductive layer ML8 may be approximately 9000 Å. The thickness of each of the seventh via VA7 and the eighth via VA8 may be approximately 6000 Å.

The ninth insulating layer INS9 may be disposed on the eighth insulating layer INS8 and the eighth conductive layer ML8. The ninth insulating layer INS9 may be formed of a silicon oxide (SiOx)-based inorganic layer, but the present disclosure is not limited thereto.

Each of the ninth vias VA9 may penetrate the ninth insulating layer INS9 and may be connected to the exposed eighth conductive layer ML8. The ninth vias VA9 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. The thickness of the ninth via VA9 may be approximately 16500 Å.

The display element layer EML may be disposed on the light emitting element backplane EBP. The display element layer EML may include light emitting elements LE each including a reflective electrode layer RL, tenth and eleventh insulating layers INS10 and INS11, a tenth via VA10, a first electrode AND, a light emitting stack ES, and a second electrode CAT; a pixel defining layer PDL; and a plurality of trenches TRC.

The reflective electrode layer RL may be disposed on the ninth insulating layer INS9. The reflective electrode layer RL may include at least one reflective electrode RL1, RL2, RL3, and/or RL4. For example, the reflective electrode layer RL may include first to fourth reflective electrodes RL1, RL2, RL3, and RL4 as shown in FIG. 7.

Each of the first reflective electrodes RL1 may be disposed on the ninth insulating layer INS9, and may be connected to the ninth via VA9. The first reflective electrodes RL1 may be formed of (Cu), aluminum (Al), tungsten (W), molybdenum (Mo), chromium (Cr), gold (Au), titanium (Ti), nickel (Ni), and/or neodymium (Nd), and/or an alloy including one or more of them. For example, the first reflective electrodes RL1 may include titanium nitride (TiN).

Each of the second reflective electrodes RL2 may be disposed on the first reflective electrode RL1. The second reflective electrodes RL2 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. For example, the second reflective electrodes RL2 may include aluminum (Al).

Each of the third reflective electrodes RL3 may be disposed on the second reflective electrode RL2. The third reflective electrodes RL3 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. For example, the third reflective electrodes RL3 may include titanium nitride (TiN).

The fourth reflective electrodes RL4 may be respectively disposed on the third reflective electrodes RL3. The fourth reflective electrodes RL4 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. For example, the fourth reflective electrodes RL4 may include titanium (Ti).

Because the second reflective electrode RL2 is an electrode that substantially reflects light from the light emitting elements LE, in one or more embodiments, the thickness of the second reflective electrode RL2 may be greater than the thickness of each of the first reflective electrode RL1, the third reflective electrode RL3, and the fourth reflective electrode RL4. For example, the thickness of each of the first reflective electrode RL1, the third reflective electrode RL3, and the fourth reflective electrode RL4 may be approximately 100 Å, and the thickness of the second reflective electrode RL2 may be 850 Å. However, in one or more other embodiments, the thickness of the second reflective electrode RL2 may be substantially the same as the thickness of each of the first reflective electrode RL1, the third reflective electrode RL3, and the fourth reflective electrode RL4.

The tenth insulating layer INS10 may be disposed on the ninth insulating layer INS9. The tenth insulating layer INS10 may be disposed between the reflective electrode layers RL adjacent to each other in a horizontal direction. In one or more embodiments, the tenth insulating layer INS10 may be disposed on the reflective electrode layer RL in the third pixel PX3. The tenth insulating layer INS10 may be formed of a silicon oxide (SiOx)-based inorganic layer, but the present disclosure is not limited thereto.

The eleventh insulating layer INS11 may be disposed on the tenth insulating layer INS10 and the reflective electrode layer RL. The eleventh insulating layer INS11 may be formed of a silicon oxide (SiOx)-based inorganic layer, but the present disclosure is not limited thereto. The tenth insulating layer INS10 and the eleventh insulating layer INS11 may be an optical auxiliary layer through which light reflected by the reflective electrode layer RL passes, from among light emitted from the light emitting elements LE.

In order to match the resonance distance of the light emitted from the light emitting elements LE in at least one of the first pixel PX1, the second pixel PX2, or the third pixel PX3, in one or more embodiments, the tenth insulating layer INS10 and the eleventh insulating layer INS11 may not be disposed under the first electrode AND of the first pixel PX1. In one or more embodiments, the first electrode AND of the first pixel PX1 may be directly disposed on the reflective electrode layer RL. The eleventh insulating layer INS11 may be disposed under the first electrode AND of the second pixel PX2. In one or more embodiments, the tenth insulating layer INS10 and the eleventh insulating layer INS11 may be disposed under the first electrode AND of the third pixel PX3.

In summary, the distance between the first electrode AND and the reflective electrode layer RL may be different in the first pixel PX1, the second pixel PX2, and the third pixel PX3. In order to adjust the distance from the reflective electrode layer RL to the second electrode CAT according to the main wavelength of the light emitted from each of the first pixel PX1, the second pixel PX2, and the third pixel PX3, the presence or absence of the tenth insulating layer INS10 and the eleventh insulating layer INS11 may be set in each of the first pixel PX1, the second pixel PX2, and the third pixel PX3. For example, it is illustrated in FIG. 7 that the distance between the first electrode AND and the reflective electrode layer RL in the third pixel PX3 is greater than the distance between the first electrode AND and the reflective electrode layer RL in the second pixel PX2 and the distance between the first electrode AND and the reflective electrode layer RL in the first pixel PX1, and the distance between the first electrode AND and the reflective electrode layer RL in the second pixel PX2 is greater than the distance between the first electrode AND and the reflective electrode layer RL in the first pixel PX1, but the present disclosure is not limited thereto.

In addition, although the tenth insulating layer INS10 and the eleventh insulating layer INS11 are illustrated in the present disclosure, a twelfth insulating layer disposed under the first electrode AND of the first pixel PX1 may be added. In this case, the eleventh insulating layer INS11 and the twelfth insulating layer may be disposed under the first electrode AND of the second pixel PX2, and the tenth insulating layer INS10, the eleventh insulating layer INS11, and the twelfth insulating layer may be disposed under the first electrode AND of the third pixel PX3.

Each of the tenth vias VA10 may penetrate the eleventh insulating layer INS11 in the first pixel PX1, the second pixel PX2, and the third pixel PX3 and may be connected to the exposed reflective electrode layer RL. The tenth vias VA10 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. The thickness of the tenth via VA10 in the second pixel PX2 may be smaller than the thickness of the tenth via VA10 in the third pixel PX3. The thickness of the tenth via VA10 in the first pixel PX1 may be smaller than the thickness of the tenth via VA10 in the second pixel PX2.

The first electrode AND of each of the light emitting elements LE may be disposed on the eleventh insulating layer INS11 and connected to the tenth via VA10. The first electrode AND of each of the light emitting elements LE may be connected to the drain region DA or source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light emitting elements LE may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. For example, the first electrode AND of each of the light emitting elements LE may be titanium nitride (TiN).

The pixel defining layer PDL may be disposed on a part of the first electrode AND of each of the light emitting elements LE. The pixel defining layer PDL may cover the edge of the first electrode AND of each of the light emitting elements LE. The pixel defining layer PDL may serve to partition the first emission areas EA1, the second emission areas EA2, and the third emission areas EA3.

The first emission area EA1 may be defined as an area in which the first electrode AND, the light emitting stack ES, and the second electrode CAT are sequentially stacked in the first pixel PX1 to emit light. The second emission area EA2 may be defined as an area in which the first electrode AND, the light emitting stack ES, and the second electrode CAT are sequentially stacked in the second pixel PX2 to emit light. The third emission area EA3 may be defined as an area in which the first electrode AND, the light emitting stack ES, and the second electrode CAT are sequentially stacked in the third pixel PX3 to emit light.

The pixel defining layer PDL may include first to third pixel defining layers PDL1, PDL2, and PDL3. The first pixel defining layer PDL1 may be disposed on the edge of the first electrode AND of each of the light emitting elements LE, the second pixel defining layer PDL2 may be disposed on the first pixel defining layer PDL1, and the third pixel defining layer PDL3 may be disposed on the second pixel defining layer PDL2. The first pixel defining layer PDL1, the second pixel defining layer PDL2, and the third pixel defining layer PDL3 may be formed of a silicon oxide (SiOₓ)-based inorganic layer, but the present disclosure is not limited thereto. The first pixel defining layer PDL1, the second pixel defining layer PDL2, and the third pixel defining layer PDL3 may each have a thickness of about 500 Å.

When the first pixel defining layer PDL1, the second pixel defining layer PDL2, and the third pixel defining layer PDL3 are formed as one pixel defining layer, the height of the one pixel defining layer increases, so that a first encapsulation inorganic layer TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

Therefore, in order to prevent the first encapsulation inorganic layer TFE1 from being cut off due to the step coverage, the first pixel defining layer PDL1, the second pixel defining layer PDL2, and the third pixel defining layer PDL3 may have a cross-sectional structure having a stepped portion. For example, the width of the first pixel defining layer PDL1 may be greater than the width of the second pixel defining layer PDL2 and the width of the third pixel defining layer PDL3, and the width of the second pixel defining layer PDL2 may be greater than the width of the third pixel defining layer PDL3. The width of the first pixel defining layer PDL1 refers to the horizontal length of the first pixel defining layer PDL1 defined in the first direction DR1 and the second direction DR2.

Each of the plurality of trenches TRC may penetrate the first pixel defining layer PDL1, the second pixel defining layer PDL2, and the third pixel defining layer PDL3. Furthermore, each of the plurality of trenches TRC may penetrate the eleventh insulating layer INS11. In one or more embodiments, the tenth insulating layer INS10 may be partially recessed at each of the plurality of trenches TRC.

At least one trench TRC may be disposed between adjacent pixels PX1, PX2, and PX3. Although FIG. 7 illustrates that two trenches TRC are disposed between adjacent pixels PX1, PX2, and PX3, the present disclosure is not limited thereto.

The light emitting stack ES may include a plurality of stack layers. FIG. 7 illustrates that the light emitting stack ES has a three-tandem structure including the first stack layer IL1, the second stack layer IL2, and the third stack layer IL3, but the present disclosure is not limited thereto. For example, the light emitting stack ES may have a two-tandem structure including two intermediate layers.

In the three-tandem structure, the light emitting stack ES may have a tandem structure including a plurality of stack layers IL1, IL2, and IL3 that emit different lights. For example, the light emitting stack ES may include the first stack layer IL1 that emits light of the first color, the second stack layer IL2 that emits light of the third color, and the third stack layer IL3 that emits light of the second color. The first stack layer IL1, the second stack layer IL2, and the third stack layer IL3 may be sequentially stacked.

The first stack layer IL1 may have a structure in which a first hole transport layer, a first organic light emitting layer that emits light of the first color, and a first electron transport layer are sequentially stacked. The second stack layer IL2 may have a structure in which a second hole transport layer, a second organic light emitting layer that emits light of the third color, and a second electron transport layer are sequentially stacked. The third stack layer IL3 may have a structure in which a third hole transport layer, a third organic light emitting layer that emits light of the second color, and a third electron transport layer are sequentially stacked.

A first charge generation layer for supplying charges to the second stack layer IL2 and supplying electrons to the first stack layer IL1 may be disposed between the first stack layer IL1 and the second stack layer IL2. The first charge generation layer may include an N-type charge generation layer that supplies electrons to the first stack layer IL1 and a P-type charge generation layer that supplies holes to the second stack layer IL2. The N-type charge generation layer may include a dopant of a metal material.

A second charge generation layer for supplying charges to the third stack layer IL3 and supplying electrons to the second stack layer IL2 may be disposed between the second stack layer IL2 and the third stack layer IL3. The second charge generation layer may include an N-type charge generation layer that supplies electrons to the second stack layer IL2 and a P-type charge generation layer that supplies holes to the third stack layer IL3.

The first stack layer IL1 may be disposed on the first electrodes AND and the pixel defining layer PDL, and may be disposed on the bottom surface of each trench TRC. Due to the trench TRC, the first stack layer IL1 may be separated between adjacent pixels PX1, PX2, and PX3. The second stack layer IL2 may be disposed on the first stack layer IL1. Due to the trench TRC, the second stack layer IL2 may be separated between adjacent pixels PX1, PX2, and PX3. A cavity ESS or an empty space may be disposed between the first stack layer IL1 and the second stack layer IL2. The third stack layer IL3 may be disposed on the second stack layer IL2. The third stack layer IL3 is not cut off by the trench TRC and may be disposed to cover the second stack layer IL2 in each of the trenches TRC. That is, in the three-tandem structure, each of the plurality of trenches TRC may be a structure for cutting off the first to second stack layers IL1 and IL2, the first charge generation layer, and the second charge generation layer of the display element layer EML between the pixels PX1, PX2, and PX3 adjacent to each other. In addition, in the two-tandem structure, each of the trenches TRC may be a structure for cutting off the charge generation layer disposed between a lower intermediate layer and an upper intermediate layer, and the lower intermediate layer.

In order to stably cut off the first and second stack layers IL1 and IL2 of the display element layer EML between adjacent pixels PX1, PX2, and PX3, the height of each of the plurality of trenches TRC may be greater than the height of the pixel defining layer PDL. The height of each of the plurality of trenches TRC refers to the length of each of the plurality of trenches TRC in the third direction DR3. The height of the pixel defining layer PDL refers to the length of the pixel defining layer PDL in the third direction DR3. In order to cut off the first to third stack layers IL1, IL2, and IL3 of the display element layer EML between the neighboring pixels PX1, PX2, and PX3, another structure may exist instead of the trench TRC. For example, instead of the trench TRC, a reverse tapered partition wall may be disposed on the pixel defining layer PDL.

The number of the stack layers IL1, IL2, and IL3 that emit different lights is not limited to that shown in FIG. 7. For example, the light emitting stack ES may include two intermediate layers. In this case, one of the two intermediate layers may be substantially the same as the first stack layer IL1, and the other may include a second hole transport layer, a second organic light emitting layer, a third organic light emitting layer, and a second electron transport layer. In this case, a charge generation layer for supplying electrons to one intermediate layer and supplying charges to the other intermediate layer may be disposed between the two intermediate layers.

In addition, FIG. 7 illustrates that the first to third stack layers IL1, IL2, and IL3 are all disposed in the first emission area EA1, the second emission area EA2, and the third emission area EA3, but the present disclosure is not limited thereto. For example, the first stack layer IL1 may be disposed in the first emission area EA1, and may not be disposed in the second emission area EA2 and the third emission area EA3. Furthermore, the second stack layer IL2 may be disposed in the second emission area EA2 and may not be disposed in the first emission area EA1 and the third emission area EA3. Further, the third stack layer IL3 may be disposed in the third emission area EA3 and may not be disposed in the first emission area EA1 and the second emission area EA2. In this case, first to third color filters CF1, CF2, and CF3 of the optical layer OPL may be omitted.

The second electrode CAT may be disposed on the third stack layer IL3. The second electrode CAT may be disposed on the third stack layer IL3 in each of the plurality of trenches TRC. The second electrode CAT may be formed of a transparent conductive material (TCO) such as ITO and/or IZO that can transmit light or a semi-transmissive conductive material such as magnesium (Mg), silver (Ag), and/or an alloy of Mg and Ag. When the second electrode CAT is formed of a semi-transmissive conductive material, the light emission efficiency may be improved in each of the first to third pixels PX1, PX2, and PX3 due to a micro-cavity effect.

The encapsulation layer TFE may be disposed on the display element layer EML. The encapsulation layer TFE may include at least one inorganic layer TFE1 and TFE2 to reduce or prevent oxygen or moisture from permeating into the display element layer EML. For example, the encapsulation layer TFE may include the first encapsulation inorganic layer TFE1 and a second encapsulation inorganic layer TFE2.

The first encapsulation inorganic layer TFE1 may be disposed on the second electrode CAT. The first encapsulation inorganic layer TFE1 may be formed as a multilayer in which one or more inorganic layers selected from silicon nitride (SiNx), silicon oxy nitride (SiON), and/or silicon oxide (SiOx) are alternately stacked. The first encapsulation inorganic layer TFE1 may be formed by a chemical vapor deposition (CVD) process.

The second encapsulation inorganic layer TFE2 may be disposed on the first encapsulation inorganic layer TFE1. The second encapsulation inorganic layer TFE2 may be formed of titanium oxide (TiOx) and/or aluminum oxide (AlOx), but the present disclosure is not limited thereto. The second encapsulation inorganic layer TFE2 may be formed by an atomic layer deposition (ALD) process. The thickness of the second encapsulation inorganic layer TFE2 may be smaller than the thickness of the first encapsulation inorganic layer TFE1.

An organic layer APL may be a layer for increasing the interfacial adhesion between the encapsulation layer TFE and the optical layer OPL. The organic layer APL may be an organic layer such as acrylic resin, epoxy resin, phenolic resin, polyamide resin, and/or polyimide resin.

The optical layer OPL includes a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be disposed on the organic layer APL.

The first color filter CF1 may overlap the first emission area EA1 of the first pixel PX1 in the third direction DR3. The first color filter CF1 may transmit light of the first color, i.e., light of a blue wavelength band. The blue wavelength band may be approximately 370 nm to 460 nm. Thus, the first color filter CF1 may transmit light of the first color from among light emitted from the first emission area EA1.

The second color filter CF2 may overlap the second emission area EA2 of the second pixel PX2. The second color filter CF2 may transmit light of the second color, i.e., light of a green wavelength band. The green wavelength band may be approximately 480 nm to 560 nm. Thus, the second color filter CF2 may transmit light of the second color from among light emitted from the second emission area EA2.

The third color filter CF3 may overlap the third emission area EA3 of the third pixel PX3. The third color filter CF3 may transmit light of the third color, i.e., light of a red wavelength band. The red wavelength band may be approximately 600 nm to 750 nm. Thus, the third color filter CF3 may transmit light of the third color from among light emitted from the third emission area EA3.

The plurality of lenses LNS may be disposed on the first color filter CF1, the second color filter CF2, and the third color filter CF3, respectively. Each of the plurality of lenses LNS may be a structure for increasing a ratio of light directed to the front of the display device 10. Each of the plurality of lenses LNS may have a cross-sectional shape that is convex in an upward direction.

The filling layer FIL may be disposed on the plurality of lenses LNS. The filling layer FIL may have a suitable refractive index (e.g., a predetermined refractive index) such that light travels in the third direction DR3 at an interface between the filling layer FIL and the plurality of lenses LNS. Further, the filling layer FIL may be a planarization layer. The filling layer FIL may be an organic layer such as acrylic resin, epoxy resin, phenolic resin, polyamide resin, and/or polyimide resin.

The cover layer CVL may be disposed on the filling layer FIL. The cover layer CVL may be a glass substrate and/or a polymer resin. When the cover layer CVL is a glass substrate, it may be attached onto the filling layer FIL. In this case, the filling layer FIL may serve to bond the cover layer CVL. When the cover layer CVL is a glass substrate, it may serve as an encapsulation substrate. When the cover layer CVL is a polymer resin, it may be directly applied onto the filling layer FIL.

The polarizing plate POL may be disposed on one surface of the cover layer CVL. The polarizing plate POL may be a structure for preventing or reducing visibility degradation caused by reflection of external light. The polarizing plate POL may include a linear polarizing plate and a phase retardation film. For example, the phase retardation film may be a λ/4 plate (quarter-wave plate), but the present disclosure is not limited thereto. However, when visibility degradation caused by reflection of external light is sufficiently overcome by the first to third color filters CF1, CF2, and CF3, the polarizing plate POL may be omitted.

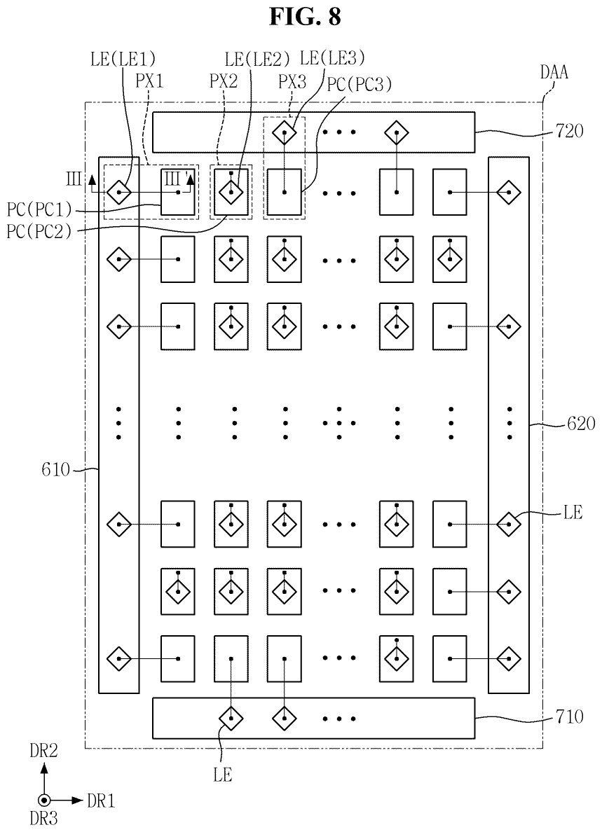

FIG. 8 is a layout diagram illustrating a part of the display panel 100 according to one or more embodiments.

The display panel 100 may include the plurality of pixels PX1, PX2, and PX3, as shown in FIG. 8. The plurality of pixels may include, for example, the first pixel PX1, the second pixel PX2, and the third pixel PX3 disposed adjacent to each other along the first direction DR1.

Each of the pixels PX1, PX2, and PX3 may include a pixel circuit PC and the light emitting element LE. In this case, the at least one light emitting element LE may overlap a driving circuit. Here, the driving circuit may be a circuit that provides various types of signals for driving the pixels PX1, PX2, and PX3 of the display panel 100. For example, the driving circuit may include the scan driver 610, the emission driver 620, the data driver 700, the first distribution circuit 710, the second distribution circuit 720, the timing control circuit 400, and the power supply circuit 500 described above.

At least one light emitting element LE may overlap, for example, at least one of the scan driver 610, the emission driver 620, the data driver 700, the first distribution circuit 710, the second distribution circuit 720, the timing control circuit 400, and/or the power supply circuit 500. FIG. 8 illustrates one embodiment in which some of the plurality of light emitting elements LE (e.g., the light emitting elements LE disposed at the edge of the display area DAA) overlap the scan driver 610, the emission driver 620, the first distribution circuit 710, and the second distribution circuit 720.

As the at least one light emitting element LE overlaps the driving circuit in this way, the area of the display area DAA may be expanded. When the plurality of light emitting elements LE overlap the scan driver 610, the emission driver 620, the first distribution circuit 710, and the second distribution circuit 720 as shown in FIG. 8, the display area DAA may be expanded to further include the scan driver 610, the emission driver 620, the first distribution circuit 710, and the second distribution circuit 720. In other words, while the above-described display area DAA of FIG. 4 is defined as an area surrounded by the scan driver 610, the emission driver 620, the first distribution circuit 710, and the second distribution circuit 720, the display area DAA of FIG. 8 may be defined as a wider area additionally including the scan driver 610, the emission driver 620, the first distribution circuit 710, and the second distribution circuit 720. Accordingly, the display area DAA of FIG. 8 may have a larger area than the display area DAA of FIG. 4. Therefore, the net die of the wafer on which the display panel 100 is manufactured may be improved. For example, assuming that a 1.3-inch display panel is manufactured on a 12-inch wafer, the net die of the wafer when the display panel with the structure of FIG. 4 is manufactured is 74, whereas the net die of the wafer when the display panel with the structure of FIG. 8 is manufactured may be 82. Therefore, when a display panel having a large display area as shown in FIG. 8 is manufactured on a wafer, the manufacturing cost of a display device may be reduced.

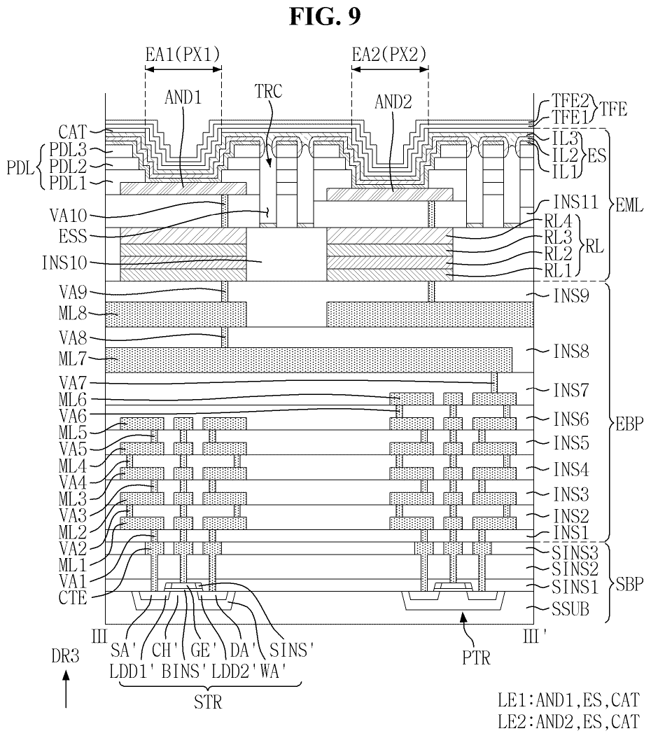

FIG. 9 is a cross-sectional view taken along the line III-III′ of FIG. 8.

As shown in FIG. 9, the first electrode may include, for example, a first anode electrode AND1 of the first pixel PX1 and a second anode electrode AND2 of the second pixel PX2.

The first anode electrode AND1 of the first pixel PX1 may be connected to a pixel circuit PC1 (hereinafter, referred to as first pixel circuit PC1 (e.g., see FIG. 8)) of the first pixel PX1. For example, because the first pixel PX1 may include the first pixel circuit PC1 and a light emitting element LE1 (hereinafter, referred to as first light emitting element LE1) connected to the first pixel circuit PC1, the first anode electrode AND1 of the first light emitting element LE1 may be connected to the pixel transistor PTR of the first pixel circuit PC1 (e.g., see FIG. 8). For example, the first anode electrode AND1 may be connected to the drain region DA of the pixel transistor PTR through the reflective electrode layer RL, a plurality of vias, and a plurality of conductive layers. The first anode electrode AND1 of the first pixel PX1 and the reflective electrode layer RL of the first pixel PX1 may not overlap the pixel transistor PTR of the first pixel PX1. In one or more embodiments, because the seventh conductive layer ML7 may be further extended in the first direction DR1 or the second direction DR2 to overlap the first anode electrode AND1, connection between the first anode electrode AND1 and the pixel transistor PTR may be facilitated even though the first anode electrode AND1 and the pixel transistor PTR do not overlap in the third direction DR3.

The second anode electrode AND2 of the second pixel PX2 may be connected to a pixel circuit PC2 (hereinafter, referred to as second pixel circuit PC2 (e.g., see FIG. 8)) of the second pixel PX2. For example, since the second pixel PX2 may include the second pixel circuit PC2 (e.g., see FIG. 8) and a light emitting element LE2 (hereinafter, referred to as second light emitting element LE2 (e.g., see FIG. 8)) connected to the second pixel circuit PC2 (e.g., see FIG. 8), the second anode electrode AND2 of the second light emitting element LE2 may be connected to the pixel transistor of the second pixel circuit PC2(e.g., see FIG. 8) .

As shown in FIGS. 8 and 9, the first light emitting element LE1 of the first pixel PX1 may overlap the scan driver 610. For example, the first emission area EA1 and the first anode electrode AND1 of the first light emitting element LE1 may overlap a scan transistor STR of the scan driver 610. The scan transistor STR may include CMOS, similarly to the pixel transistor described above. For example, the scan transistor STR may include the gate electrode GE′, the channel region CH′, the source region SA′, the drain region DA′, the first low-concentration impurity region LDD1′, the second low-concentration impurity region LDD2′, the lower insulating layer BINS′, and the side insulating layer SINS′.

In one or more embodiments, the second light emitting element LE2 (e.g., see FIG. 8) of the second pixel PX2 may not overlap the driving circuit. For example, as shown in FIG. 9, the second light emitting element LE2 of the second pixel PX2 may overlap the pixel circuit PC of another pixel (e.g., the first pixel circuit PC1 of the first pixel PX1). As shown in FIG. 9, the second anode electrode AND2 of the second light emitting element LE2 may overlap the pixel transistor PTR provided in the first pixel circuit PC1.

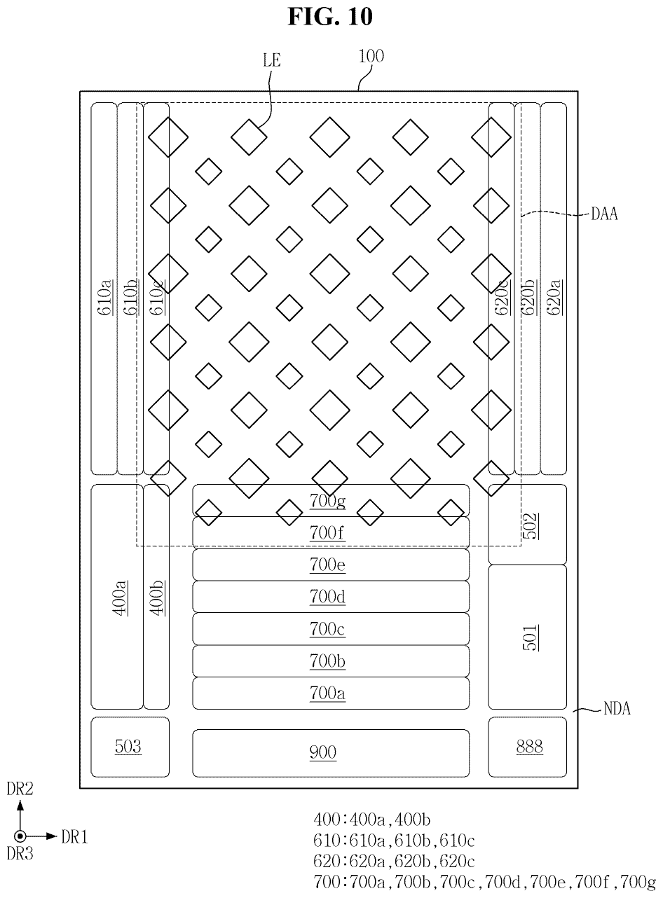

In one or more embodiments, the third pixel PX3 may include a third pixel circuit PC3 (e.g., see FIG. 8) and a third light emitting element LE3 connected thereto. An anode electrode (hereinafter, referred to as third anode electrode) of the third light emitting element LE3 may overlap the driving circuit. For example, as shown in FIG. 8, the third emission area and the third anode electrode of the third light emitting element LE3 may overlap the second distribution circuit 720 (for example, the non-pixel transistor of the second distribution circuit 720) in the third direction DR3. p FIG. 10 is a layout diagram of the display panel 100 according to one or more embodiments.

The scan driver 610 may include a scan shift register 610a, a scan level shifter 610b, and a scan buffer 610c.

The scan shift register 610a may receive a scan shift clock and a scan start pulse from the timing control circuit 400, and sequentially generate a plurality of scan signals while shifting the scan start pulse for each cycle of the scan shift clock.

The scan level shifter 610b may convert the levels of the plurality of scan signals from the scan shift register 610a and provide them to the scan buffer 610c.

The scan buffer 610c may buffer and output the plurality of scan signals from the scan level shifter 610b.

The emission driver 620 may include an emission shift register 620a, an emission level shifter 620b, and an emission buffer 620c.

The emission shift register 620a may receive an emission shift clock and an emission start pulse from the timing control circuit 400, and sequentially generate a plurality of emission control signals while shifting the emission start pulse for each cycle of the emission shift clock.

The emission level shifter 620b may convert the levels of the plurality of emission control signals from the emission shift register 620a and provide them to the emission buffer 620c.

The emission buffer 620c may buffer and output the plurality of emission control signals from the emission level shifter 620b.

A grayscale voltage circuit 501 may divide a gamma reference voltage to generate a plurality of grayscale voltages, and provide them to the data driver 700. For example, the grayscale voltage circuit 501 may generate a plurality of red grayscale voltages for red image data, a plurality of green grayscale voltages for green image data, and a plurality of blue grayscale voltages for blue image data.

An interface circuit 900 may convert serial image data from the outside into parallel image data and provide them to the data driver 700.

The data driver 700 may include a data shift register 700a, a data sampling latch 700b, a data holding latch 700c, a data level shifter 700d, a digital-to-analog converter 700e, a data buffer 700f, and a demultiplexer 700g. Here, the demultiplexer 700g may include the aforementioned first distribution circuit 710. In other words, the data driver 700 may further include the first distribution circuit 710.

The data shift register 700a may receive a source shift clock and a source start pulse from the timing control circuit 400, and sequentially generate a plurality of sampling signals while shifting the source start pulse for each cycle of the source shift clock.

The data sampling latch 700b may sequentially store a plurality of digital image data signals in response to the plurality of sampling signals sequentially supplied from the data shift register 700a.

In response to a source output control signal, the data holding latch 700c may concurrently (e.g., simultaneously) receive and store the plurality of image data signals from the data sampling latch 700b, and concurrently (e.g., simultaneously) output a plurality of sampled image data signals stored in a previous period. The plurality of image data signals outputted from the data holding latch 700c may be concurrently (e.g., simultaneously) supplied to the data level shifter 700d.

The data level shifter 700d may convert the levels of the image data signals from the data holding latch 700c and provide them to the digital-to-analog converter 700e.

The digital-to-analog converter 700e may generate analog image data signals corresponding to the respective bit values of the plurality of image data signals supplied from the data level shifter 700d. For example, the digital-to-analog converter 700e may select, from a grayscale generator, a grayscale voltage corresponding to the bit value of the digital image data signal from the data holding latch 700c, and may output the selected grayscale voltage as the analog image data signal.

The data buffer 700f may receive the analog image data signals from the digital-to-analog converter 700e, amplify the received analog image data signals, and output them. The analog image data signals from the data buffer 700f may be provided to the demultiplexer 700g.

The timing control circuit 400 may include a first timing controller 400a and a timing buffer 400b.

The first timing controller 400a may output the above-described source shift clock, source start pulse, source output control signal, scan shift clock, scan start pulse, emission shift clock, and emission start pulse.

The timing buffer 400b may buffer the signals from the first timing controller 400a and provide the buffered signals to the scan driver 610, the emission driver 620, and the data driver 700 described above.

A second timing controller 502 may control an input timing of the grayscale voltage supplied from the grayscale voltage circuit 501 to the digital-to-analog converter 700e.

A sensor circuit 888 may include a circuit for driving a touch sensor of the display panel 100.

A regulator 503 may generate various types of powers required to drive the display panel 100. The regulator 503 may be included in the power supply circuit 500.

The light emitting element LE may overlap the driving circuit of the display device 10. For example, the driving circuit of the display device 10 may include the above-described scan shift register 610a, scan level shifter 610b, scan buffer 610c, emission shift register 620a, emission level shifter 620b, emission buffer 620c, grayscale voltage circuit 501, interface circuit 900, data shift register 700a, data sampling latch 700b, data holding latch 700c, data level shifter 700d, digital-to-analog converter 700e, data buffer 700f, demultiplexer 700g, first timing controller 400a, timing buffer 400b, second timing controller 502, sensor circuit 888, regulator 503, and so forth, and at least one light emitting element LE may overlap at least one of the components of the driving circuit stated above.

FIG. 10 illustrates an example in which some of the plurality of light emitting elements LE overlap the scan buffer 610c, the emission buffer 620c, the demultiplexer 700g, the data buffer 700f, the second timing controller 502, and the timing buffer 400b. For example, as shown in FIG. 10, the first electrode of each of some of the plurality of light emitting elements LE may overlap at least the non-pixel transistor of the scan buffer 610c, the non-pixel transistor of the emission buffer 620c, the non-pixel transistor of the demultiplexer 700g, the non-pixel transistor of the data buffer 700f in the third direction DR3, and the non-pixel transistors of each of the second timing controller 502, and the timing buffer 400b. Accordingly, the display area DAA may be expanded.

The light emitting elements LE may have different sizes. For example, the first electrode (or emission area) of the red light emitting element LE providing red light, the first electrode (or emission area) of the green light emitting element LE providing green light, and the first electrode (or emission area) of the blue light emitting element LE providing blue light may have different sizes.

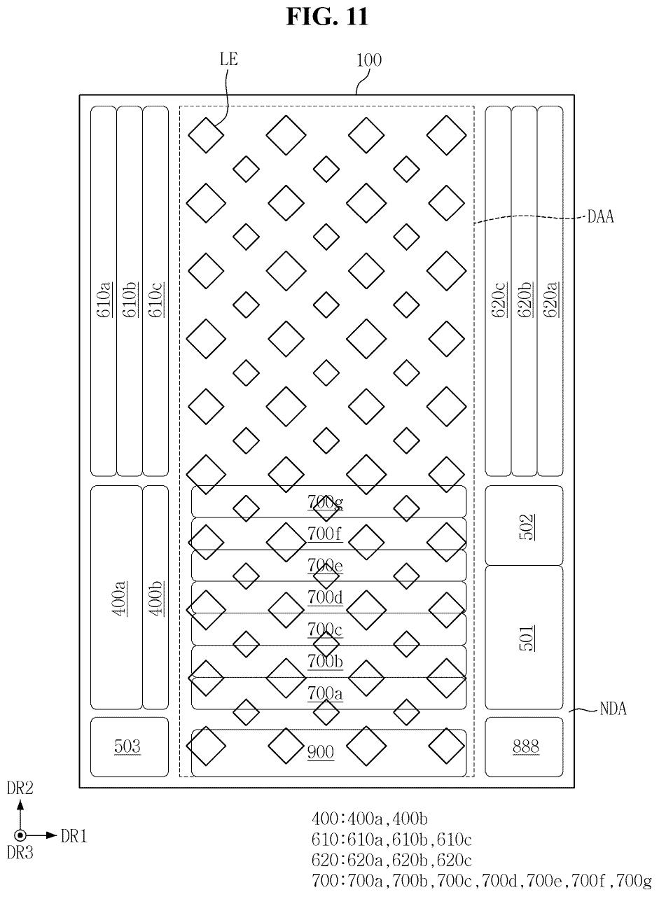

FIG. 11 is a layout diagram of the display panel 100 according to one or more embodiments.

The display panel 100 of FIG. 11 is different from the display device 10 of FIG. 10 described above in terms of the area of the display area DAA, and the following description will mainly focus on this difference.

FIG. 11 illustrates an example in which some of the plurality of light emitting elements LE overlap the data shift register 700a, the data sampling latch 700b, the data holding latch 700c, the data level shifter 700d, the digital-to-analog converter 700e, the data buffer 700f, the demultiplexer 700g, and the interface circuit 900. For example, as shown in FIG. 11, the first electrode of each of some of the plurality of light emitting elements LE may overlap the non-pixel transistor of the data shift register 700a, the non-pixel transistor of the data sampling latch 700b, the non-pixel transistor of the data holding latch 700c, the non-pixel transistor of the data level shifter 700d, the non-pixel transistor of the digital-to-analog converter 700e, the non-pixel transistor of the data buffer 700f, the non-pixel transistor of the demultiplexer 700g, and the non-pixel transistor of the interface circuit 900 in the third direction DR3. Accordingly, the display area DAA may be expanded.

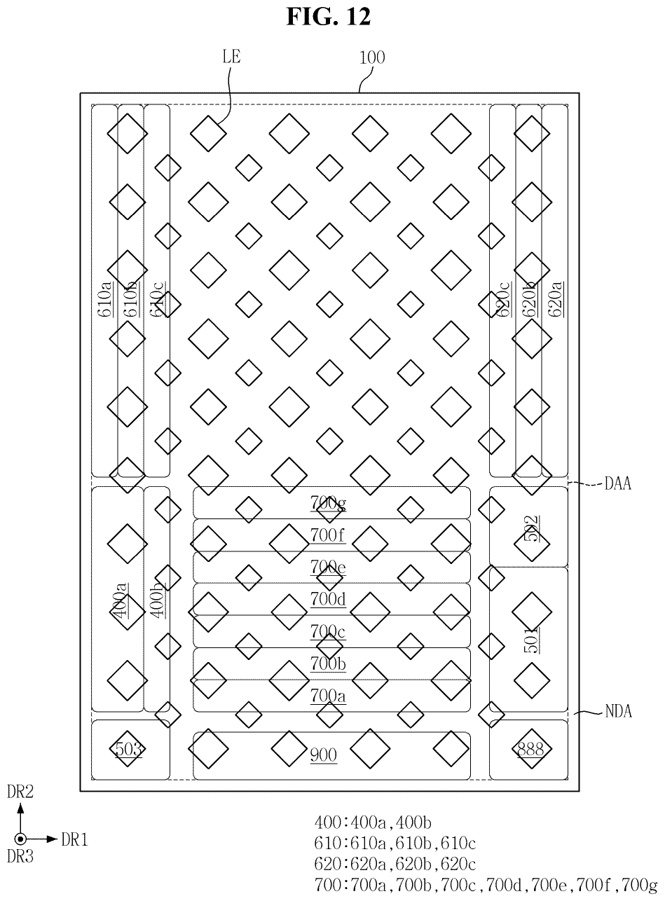

FIG. 12 is a layout diagram of the display panel 100 according to one or more embodiments.

The display panel 100 of FIG. 12 differs from the display device 10 of FIG. 10 described above in terms of the area of the display area DAA, and the following description will mainly focus on this difference.

FIG. 12 illustrates an example in which some of the plurality of light emitting elements LE overlap the scan shift register 610a, the scan level shifter 610b, the scan buffer 610c, the emission shift register 620a, the emission level shifter 620b, the emission buffer 620c, the grayscale voltage circuit 501, the interface circuit 900, the data shift register 700a, the data sampling latch 700b, the data holding latch 700c, the data level shifter 700d, the digital-to-analog converter 700e, the data buffer 700f, the demultiplexer 700g, the first timing controller 400a, the timing buffer 400b, the second timing controller 502, the sensor circuit 888, and the regulator 503. For example, as shown in FIG. 12, the first electrode of each of some of the plurality of light emitting elements LE may overlap the non-pixel transistor of the scan shift register 610a, the non-pixel transistor of the scan level shifter 610b, the non-pixel transistor of the scan buffer 610c, the non-pixel transistor of the emission shift register 620a, the non-pixel transistor of the emission level shifter 620b, the non-pixel transistor of the emission buffer 620c, the non-pixel transistor of the grayscale voltage circuit 501, the non-pixel transistor of the interface circuit 900, the non-pixel transistor of the data shift register 700a, the non-pixel transistor of the data sampling latch 700b, the non-pixel transistor of the data holding latch 700c, the non-pixel transistor of the data level shifter 700d, the non-pixel transistor of the digital-to-analog converter 700e, the non-pixel transistor of the data buffer 700f, the non-pixel transistor of the demultiplexer 700g, the non-pixel transistor of the first timing controller 400a, the non-pixel transistor of the timing buffer 400b, the non-pixel transistor of the second timing controller 502, the sensor circuit 888, and the non-pixel transistor of the regulator 503 in the third direction DR3. Accordingly, the display area DAA may be expanded.

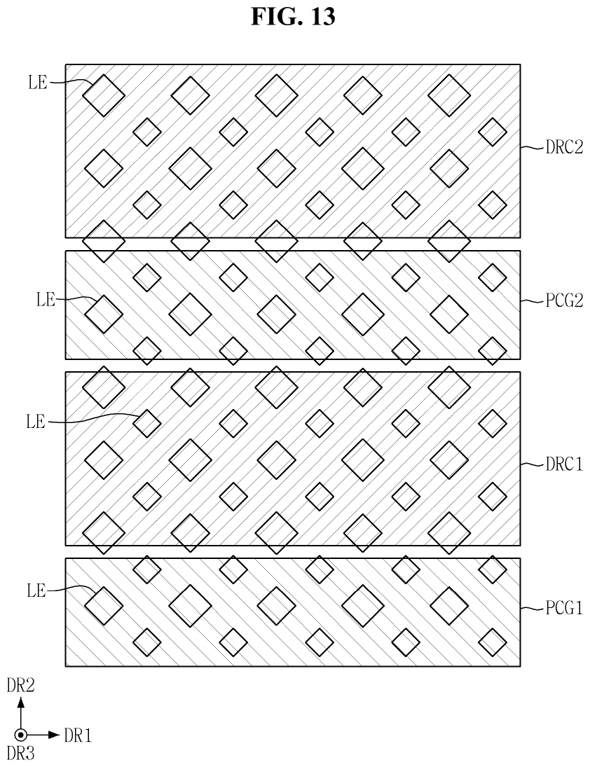

FIG. 13 is a diagram illustrating a part of the display area DAA of the display panel 100 according to one or more embodiments.

As shown in FIG. 13, a plurality of pixel circuit groups PCG1 and PCG2 and a plurality of driving circuits DRC1 and DRC2 may be alternately disposed in the display area DAA of the display panel 100 along the second direction DR2. For example, the first driving circuit DRC1 may be disposed between the first pixel circuit group PCG1 and the second pixel circuit group PCG2, and the second pixel circuit group PCG2 may be disposed between the first driving circuit DRC1 and the second driving circuit DRC2.

Each of the pixel circuit groups PCG1 and PCG2 may include a plurality of pixel circuits PC.

For example, the first pixel circuit group PCG1 may include the plurality of pixel circuits PC respectively connected to a plurality of light emitting elements LE overlapping the first pixel circuit group PCG1 (e.g., the plurality of pixel circuits PC belonging to the first pixel circuit group PCG1) and a plurality of light emitting elements LE overlapping the first driving circuit DRC1. In other words, the plurality of pixel circuits PC for driving the plurality of light emitting elements LE on the first pixel circuit group PCG1 and the plurality of light emitting elements LE on the first driving circuit DRC1 may be integrated at high density in the first pixel circuit group PCG1.

The second pixel circuit group PCG2 may include the plurality of pixel circuits PC respectively connected to a plurality of light emitting elements LE overlapping the second pixel circuit group PCG2 (e.g., the plurality of pixel circuits PC belonging to the second pixel circuit group PCG2) and a plurality of light emitting elements LE overlapping the second driving circuit DRC2. In other words, the plurality of pixel circuits PC for driving the plurality of light emitting elements LE on the second pixel circuit group PCG2 and the plurality of light emitting elements LE on the second driving circuit DRC2 may be integrated at high density in the second pixel circuit group PCG2.

The first driving circuit DRC1 may include, for example, one of the scan shift register 610a, the scan level shifter 610b, the scan buffer 610c, the emission shift register 620a, the emission level shifter 620b, the emission buffer 620c, the grayscale voltage circuit 501, the interface circuit 900, the data shift register 700a, the data sampling latch 700b, the data holding latch 700c, the data level shifter 700d, the digital-to-analog converter 700e, the data buffer 700f, the demultiplexer 700g, the first timing controller 400a, the timing buffer 400b, the second timing controller 502, the sensor circuit 888, and/or the regulator 503 of FIG. 10.

The second driving circuit DRC2 may include, for example, the other one of the scan shift register 610a, the scan level shifter 610b, the scan buffer 610c, the emission shift register 620a, the emission level shifter 620b, the emission buffer 620c, the grayscale voltage circuit 501, the interface circuit 900, the data shift register 700a, the data sampling latch 700b, the data holding latch 700c, the data level shifter 700d, the digital-to-analog converter 700e, the data buffer 700f, the demultiplexer 700g, the first timing controller 400a, the timing buffer 400b, the second timing controller 502, the sensor circuit 888, and/or the regulator 503 of FIG. 10. For example, the first driving circuit DRC1 and the second driving circuit DRC2 may be driving circuits including different components.

According to FIG. 13, the plurality of pixel circuit groups PCG1 and PCG2 and the plurality of driving circuits DRC1 and DRC2 are alternately disposed along the second direction DR2. Accordingly, although the display area DAA is expanded, an increase of the distance between the light emitting elements LE overlapping the driving circuits DRC1 and DRC2 and the pixel circuits PC for driving those light emitting elements LE may be prevented. Accordingly, electrical connection between the light emitting elements LE on the driving circuits DRC1 and DRC2 and the pixel circuits PC for driving the light emitting elements LE may be facilitated.

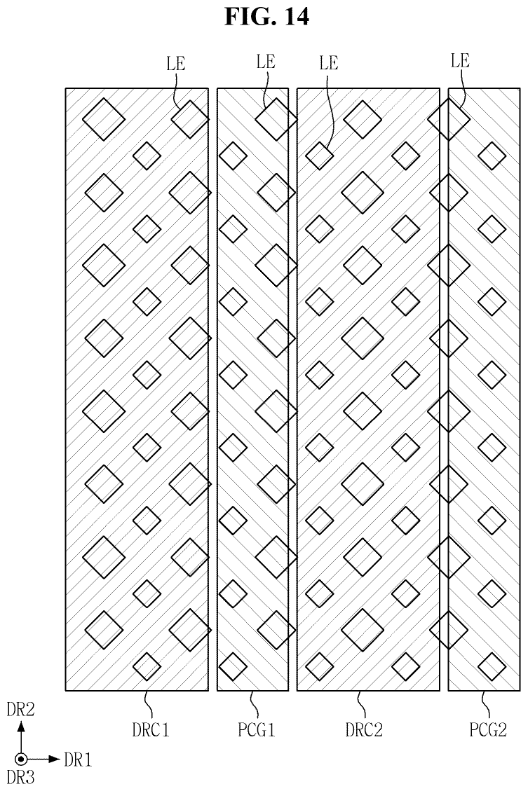

FIG. 14 is a diagram illustrating a part of the display area DAA of the display panel 100 according to one or more embodiments.

As shown in FIG. 14, a plurality of driving circuits and a plurality of pixel circuit groups may be alternately disposed in the display area DAA of the display panel 100 along the first direction DR1. For example, the first pixel circuit group PCG1 may be disposed between the first driving circuit DRC1 and the second driving circuit DRC2, and the second driving circuit DRC2 may be disposed between the first pixel circuit group PCG1 and the second pixel circuit group PCG2.

The first pixel circuit group PCG1 may include the plurality of pixel circuits PC respectively connected to the plurality of light emitting elements LE overlapping the first pixel circuit group PCG1 (e.g., the plurality of pixel circuits PC belonging to the first pixel circuit group PCG1) and the plurality of light emitting elements LE overlapping the first driving circuit DRC1. In other words, the plurality of pixel circuits PC for driving the plurality of light emitting elements LE on the first pixel circuit group PCG1 and the plurality of light emitting elements LE on the first driving circuit DRC1 may be integrated at high density in the first pixel circuit group PCG1.

The second pixel circuit group PCG2 may include the plurality of pixel circuits PC respectively connected to a plurality of light emitting elements LE overlapping the second pixel circuit group PCG2 (e.g., the plurality of pixel circuits PC belonging to the second pixel circuit group PCG2) and a plurality of light emitting elements LE overlapping the second driving circuit DRC2. In other words, the plurality of pixel circuits PC for driving the plurality of light emitting elements LE on the second pixel circuit group PCG2 and the plurality of light emitting elements LE on the second driving circuit DRC2 may be integrated at high density in the second pixel circuit group PCG2.

According to FIG. 14, the plurality of driving circuits DRC1 and DRC2 and the plurality of pixel circuit groups PCG1 and PCG2 are alternately disposed along the first direction DR1. Accordingly, even though the display area DAA is expanded, an increase of the distance between the light emitting elements LE overlapping the driving circuits DRC1 and DRC2 and the pixel circuits PC for driving those light emitting elements LE may be prevented or reduced. Accordingly, electrical connection between the light emitting elements LE on the driving circuits DRC1 and DRC2 and the pixel circuits PC for driving the light emitting elements LE may be facilitated.

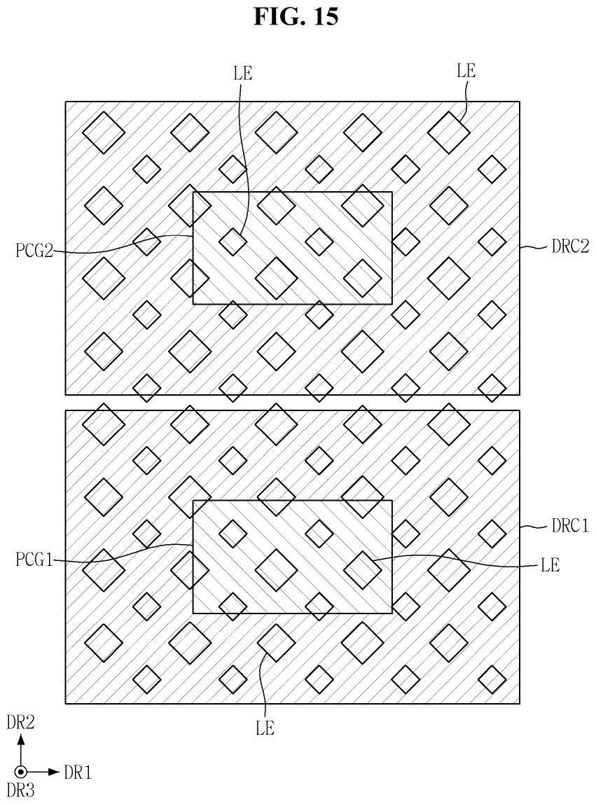

FIG. 15 is a diagram illustrating a part of the display area DAA of the display panel 100 according to one or more embodiments.

As illustrated in FIG. 15, the plurality of pixel circuit groups PCG1 and PCG2 may be surrounded by the plurality of driving circuits DRC1 and DRC2. For example, the first pixel circuit group PCG1 may be surrounded by the first driving circuit DRC1, and the second pixel circuit group PCG2 may be surrounded by the second driving circuit DRC2.

The first pixel circuit group PCG1 may include the plurality of pixel circuits PC respectively connected to the plurality of light emitting elements LE overlapping the first pixel circuit group PCG1 (e.g., the plurality of pixel circuits PC belonging to the first pixel circuit group PCG1) and the plurality of light emitting elements LE overlapping the first driving circuit DRC1. In other words, the plurality of pixel circuits PC for driving the plurality of light emitting elements LE on the first pixel circuit group PCG1 and the plurality of light emitting elements LE on the first driving circuit DRC1 may be integrated at high density in the first pixel circuit group PCG1.

The second pixel circuit group PCG2 may include the plurality of pixel circuits PC respectively connected to a plurality of light emitting elements LE overlapping the second pixel circuit group PCG2 (e.g., the plurality of pixel circuits PC belonging to the second pixel circuit group PCG2) and a plurality of light emitting elements LE overlapping the second driving circuit DRC2. In other words, the plurality of pixel circuits PC for driving the plurality of light emitting elements LE on the second pixel circuit group PCG2 and the plurality of light emitting elements LE on the second driving circuit DRC2 may be integrated at high density in the second pixel circuit group PCG2.

According to FIG. 15, the plurality of driving circuits DRC1 and DRC2 and the plurality of pixel circuit groups PCG1 and PCG2 are alternately disposed along the second direction DR2. Accordingly, even though the display area DAA is expanded, an increase of the distance between the light emitting elements LE overlapping the driving circuits DRC1 and DRC2 and the pixel circuits PC for driving those light emitting elements LE may be prevented or reduced. Accordingly, electrical connection between the light emitting elements LE on the driving circuits DRC1 and DRC2 and the pixel circuits PC for driving the light emitting elements LE may be facilitated.

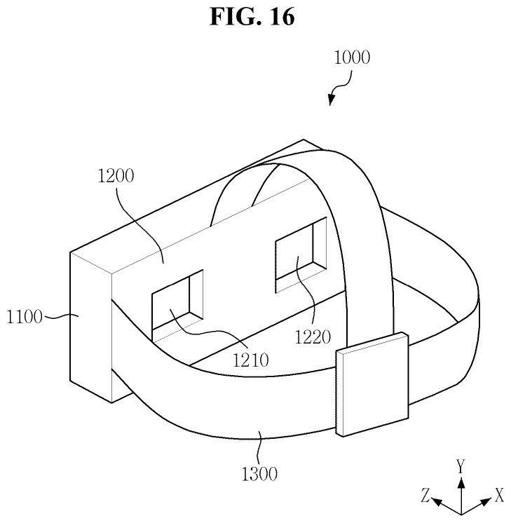

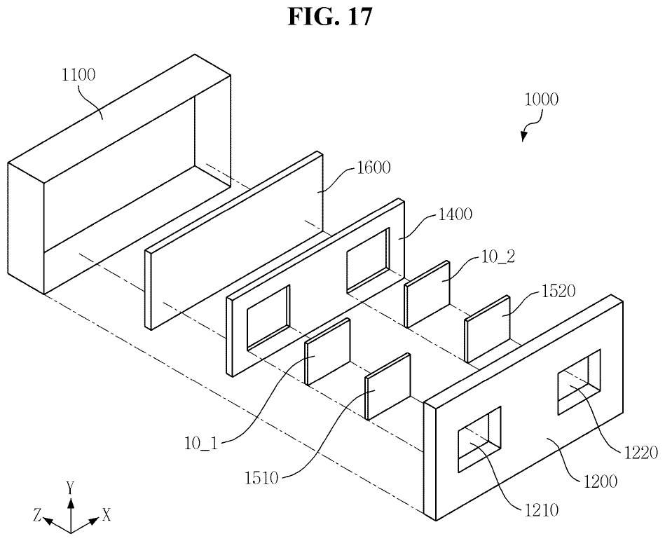

FIG. 16 is a perspective view illustrating a head mounted display according to one or more embodiments. FIG. 17 is an exploded perspective view illustrating an example of the head mounted display of FIG. 16.

Referring to FIGS. 16 and 17, a head mounted display 1000 according to one or more embodiments includes a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 provides an image to the user's left eye, and the second display device 10_2 provides an image to the user's right eye. Because each of the first display device 10_1 and the second display device 10_2 is substantially the same as the display device 10 described in conjunction with FIG. 1-15, description of the first display device 10_1 and the second display device 10_2 will be omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first display device 10_1 and the control circuit board 1600 and between the second display device 10_2 and the control circuit board 1600. The middle frame 1400 serves to support and fix the first display device 10_1, the second display device 10_2, and the control circuit board 1600.

The control circuit board 1600 may be disposed between the middle frame 1400 and the display device housing 1100. The control circuit board 1600 may be connected to the first display device 10_1 and the second display device 10_2 through the connector. The control circuit board 1600 may convert an image source inputted from the outside into digital video data DATA, and transmit the digital video data DATA to the first display device 10_1 and the second display device 10_2 through the connector.

The control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. Alternatively, the control circuit board 1600 may transmit the same digital video data DATA to the first display device 10_1 and the second display device 10_2.

The display device housing 1100 serves to accommodate the first display device 10_1, the second display device 10_2, the middle frame 1400, the first optical member 1510, the second optical member 1520, and the control circuit board 1600. The housing cover 1200 is disposed to cover one open surface of the display device housing 1100. The housing cover 1200 may include the first eyepiece 1210 at which the user's left eye is disposed and the second eyepiece 1220 at which the user's right eye is disposed. FIGS. 16 and 17 illustrate that the first eyepiece 1210 and the second eyepiece 1220 are disposed separately, but the present disclosure is not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

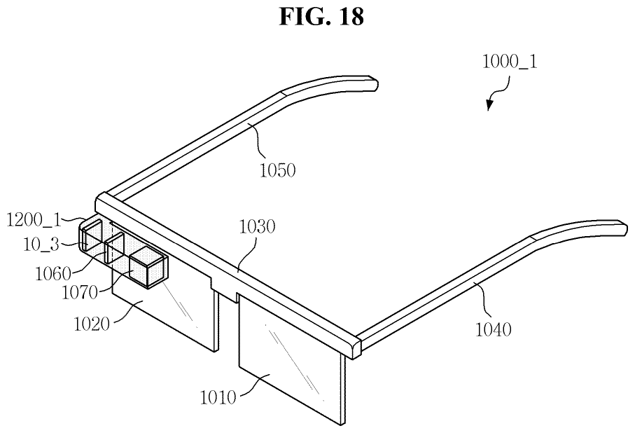

The head mounted band 1300 serves to secure the display device housing 1100 to the user's head such that the first eyepiece 1210 and the second eyepiece 1220 of the housing cover 1200 remain disposed on the user's left and right eyes, respectively. When the display device housing 1200 is implemented to be lightweight and compact, the head mounted display 1000 may be provided with, as shown in FIG. 18, an eyeglass frame instead of the head mounted band 1300.

In addition, the head mounted display 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, and/or a Bluetooth module.

FIG. 18 is a perspective view illustrating a head mounted display according to one or more embodiments.

Referring to FIG. 18, a head mounted display 1000_1 according to one or more embodiments may be an eyeglasses-type display device in which a display device housing 1200_1 is implemented in a lightweight and compact manner. The head mounted display 1000_1 according to one or more embodiments may include a display device 10_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 10_3, the optical member 1060, and the optical path changing member 1070. The image displayed on the display device 10_3 may be magnified by the optical member 1060, and may be provided to the user's right eye through the right eye lens 1020 after the optical path thereof is changed by the optical path changing member 1070. As a result, the user may view an augmented reality image, through the right eye, in which a virtual image displayed on the display device 10_3 and a real image seen through the right eye lens 1020 are combined.

FIG. 18 illustrates that the display device housing 1200_1 is disposed at the right end of the support frame 1030, but the present disclosure is not limited thereto. For example, the display device housing 1200_1 may be disposed at the left end of the support frame 1030, and in this case, the image of the display device 10_3 may be provided to the user's left eye. Alternatively, the display device housing 1200_1 may be disposed at both the left and right ends of the support frame 1030, and in this case, the user may view the image displayed on the display device 10_3 through both the left and right eyes.

In concluding the detailed description, those skilled in the art will appreciate that many variations and modifications can be made to the embodiments without substantially departing from the principles, spirit, and scope of the present disclosure. Therefore, the disclosed embodiments of the present disclosure are used in a generic and descriptive sense only and not for purposes of limitation.

What is claimed is:

1. A display device comprising:
a substrate;
a pixel circuit on the substrate;
a light emitting element connected to the pixel circuit; and
a driving circuit connected to the pixel circuit,
wherein the light emitting element overlaps the driving circuit.

2. The display device of claim 1, wherein the light emitting element comprises:
a first electrode on the substrate;
a light emitting layer on the first electrode; and
a second electrode on the light emitting layer.

3. The display device of claim 2, wherein the first electrode of the light emitting element overlaps the driving circuit.

4. The display device of claim 2, further comprising a pixel defining layer on the first electrode of the light emitting element and defining an emission area of the light emitting element.

5. The display device of claim 4, wherein the emission area overlaps the driving circuit.

6. The display device of claim 1, wherein the light emitting element overlaps a non-pixel transistor of the driving circuit.

7. The display device of claim 1, wherein the pixel circuit and the driving circuit are alternately arranged.

8. The display device of claim 1, wherein the pixel circuit is surrounded by the driving circuit.

9. The display device of claim 1, wherein the driving circuit comprises at least one of:
a scan driver connected to the pixel circuit through a scan line;
an emission driver connected to the pixel circuit through an emission control line;
a data driver connected to the pixel circuit through a data line; or
a timing control circuit connected to the scan driver, the emission driver, and the data driver.

10. The display device of claim 1, further comprising a reflective electrode layer connected to the light emitting element.

11. The display device of claim 10, wherein the reflective electrode layer overlaps the driving circuit.

12. A display device comprising:
a substrate;
a plurality of pixel circuits on the substrate;
a plurality of light emitting elements respectively connected to the pixel circuits; and
a driving circuit connected to at least one pixel circuit,
wherein the plurality of light emitting elements comprises:
a first light emitting element overlapping the driving circuit; and
a second light emitting element that does not overlap the driving circuit.

13. The display device of claim 12, wherein the first light emitting element comprises:
a first electrode on the substrate;
a light emitting layer on the first electrode; and
a second electrode on the light emitting layer.

14. The display device of claim 13, wherein the first electrode of the first light emitting element overlaps the driving circuit.

15. The display device of claim 13, further comprising a pixel defining layer on the first electrode of the first light emitting element and defining an emission area of the first light emitting element.

16. The display device of claim 15, wherein the emission area overlaps the driving circuit.

17. The display device of claim 12, wherein the first light emitting element overlaps a non-pixel transistor of the driving circuit.

18. The display device of claim 12, wherein the driving circuit and a pixel circuit connected to the first light emitting element are alternately arranged.

19. The display device of claim 12, wherein a pixel circuit connected to the first light emitting element is surrounded by the driving circuit.

20. The display device of claim 12, wherein the driving circuit comprises at least one of:
a scan driver connected to the pixel circuit through a scan line;
an emission driver connected to the pixel circuit through an emission control line;
a data driver connected to the pixel circuit through a data line; or
a timing control circuit connected to the scan driver, the emission driver, and the data driver.
